(19) United States
(12) Patent Application Publication
(10) Pub. No.: US 2025/0384907 A1
(43) Pub. Date: Dec. 18, 2025

(54) BIAS CURRENT GENERATION METHODS AND SYSTEMS FOR FAST CURRENT SENSING

(71) Applicant: Micron Technology, Inc., Boise, ID (US)

(72) Inventors: Qui Nguyen, San Jose, CA (US); Jun Xu, San Jose, CA (US); Luyen Vu, San Jose, CA (US); Kitae Park, San Jose, CA (US); Tomoharu Tanaka, Kanagawa (JP); Erwin E Yu, San Jose, CA (US)

(73) Assignee: Micron Technology, Inc., Boise, ID (US)

(21) Appl. No.: 19/239,687

(22) Filed: Jun. 16, 2025

Related U.S. Application Data
(60) Provisional application No. 63/661,547, filed on Jun. 18, 2024.

(51) Int. Cl. G11C 7/22; G11C 7/06; G11C 7/12; G11C 8/08

(52) U.S. Cl. CPC G11C 7/22; G11C 7/06; G11C 7/12; G11C 8/08; G11C 2207/063

(57) ABSTRACT

Methods, systems, and devices for techniques for faster sensing operation are provided. In one embodiment, a memory device comprises a data line; a plurality of memory blocks coupled to the data line; and a dedicated memory block coupled to the data line. The dedicated memory block is controllable to generate a sensing current. The memory device further comprises a memory controller configured to, during sensing of a selected memory block of the plurality of memory blocks, cause one or more regulators to: drive the selected memory block such that a pillar current flows through a pillar of the selected memory block, and drive the dedicated memory block to generate the sensing current. The memory device further comprises a sense amplifier configured to sense a data line current. The data line current is a combination of the pillar current and the sensing current.

### CROSS-REFERENCE TO RELATED APPLICATION

This application claims priority to U.S. Provisional Application No. 63/661,547, filed on Jun. 18, 2024, entitled “BIAS CURRENT GENERATION METHODS AND SYSTEMS FOR FAST CURRENT SENSING,” the content of which is incorporated by reference in its entirety for all purposes.

### TECHNICAL FIELD

This disclosure relates to one or more systems for memory, including techniques for fast current sensing in a memory device.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells. Information can also be erased from the memory cells and new information can be stored in the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

FIG. 1 is a block diagram of a memory device in communication with a memory system controller of a memory system, in accordance with examples as disclosed herein.

FIGS. 2A-2C are illustrative schematics of portions of an array of memory calls in a memory device, in accordance with examples as disclosed herein.

FIG. 2D illustrates an example of a memory device including multiple blocks of memory cells grouped into memory planes in accordance with examples as disclosed herein.

FIG. 3 is a block diagram of an example apparatus for implementing one or more systems and for performing one or more methods described herein, in accordance with examples as disclosed herein.

FIGS. 4A-4B illustrate an example three-dimensional structure of a memory device in accordance with examples as disclosed herein.

FIG. 5 illustrates an example memory device with sensing current generation capabilities for fast data line current sensing in accordance with examples as disclosed herein.

FIG. 6 illustrates an example memory device using a dedicated memory block for fast data line current sensing in accordance with examples as disclosed herein.

FIG. 7 illustrates an example memory device using a Read Only Memory (ROM) block for fast data line current sensing in accordance with examples as disclosed herein.

FIG. 8 illustrates a flowchart showing a method or methods that support techniques for fast data line current sensing in accordance with examples as disclosed herein.

### DETAILED DESCRIPTION

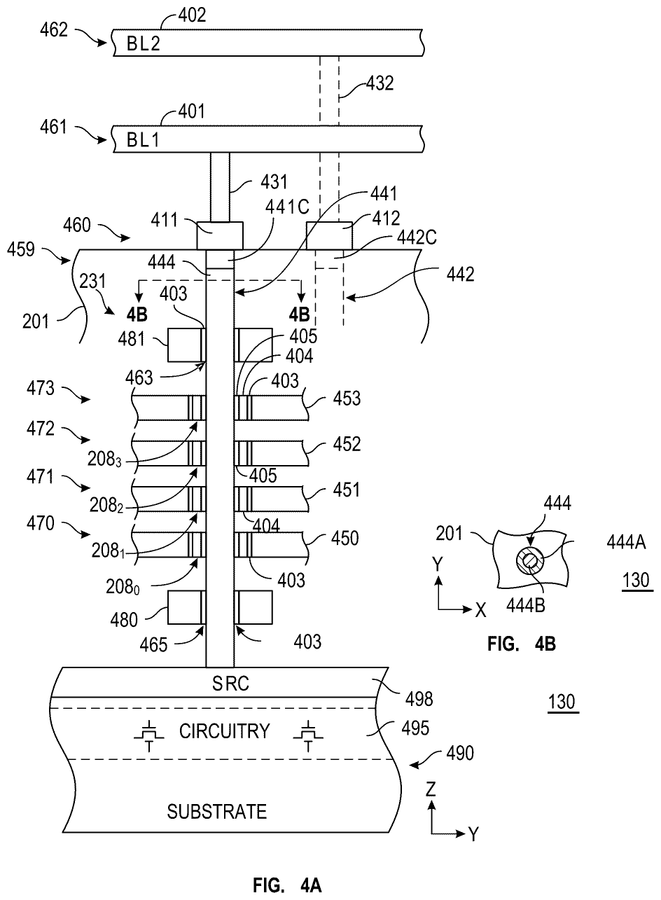

A memory device has many memory cells. Memory cells in a memory device are connected to access lines (e.g., word lines) and data lines (e.g., bit lines). Data stored in the memory cells can be accessed by applying particular control signals to the access lines and sensing the currents in the data lines. Nowadays, a memory device may have a three-dimensional (3D) structure, which has a higher storage capacity than a two-dimensional (2D) device. In a typical 3D memory device (e.g., device 130 as shown FIG. 4A), the memory device may have multiple levels of memory cells. The multiple levels of memory cells may be stacked vertically and connected using vertical channels such as semiconductor pillars (e.g., pillars 441 and 442 in FIG. 4A). Data lines 401 and 402 (e.g., bit lines in FIG. 4A) are electrically connected to the pillars. As the number of levels of memory cells increases, the length (or height) of the pillar connected to the memory cells also increases. As a result, the resistance associated with the pillar increases. Because the pillar is electrically connected to the data line, the overall resistance associated with the data line therefore also increases.

During a memory cell sensing operation (e.g., a read operation, a program verification operation, etc.), the data line current is sensed by a sense circuit. Thus, during a sensing operation, increasing the overall resistance associated with a data line decreases the sensing current flowing through the data line. For instance, the data line current may significantly decrease (e.g., decreased by 2-10 times) when the overall resistance associated with the data line increases. The data line current is used for sensing the stored data in the memory cells. The magnitude of the data line current is inversely proportional to the data line settling time. Accordingly, the greater the magnitude of the data line current, the shorter the data line settling time. And when the magnitude of the data line current decreases, the data line settling time becomes longer. Using the above example, when the data line current decreases by 2-10 times, the data line settling time may increase significantly (e.g., a 2-10 times increase). The significantly-increased data line settling time may severely impact the speed of memory cell sensing operations. Such operations may include, for example, the read operation, the program verification operation, etc. These memory cell sensing operations become slower, which reduces the overall performance of the memory device. Therefore, there is a need to improve the data line settling time for memory devices that have more and more stacked levels of memory cells (and thus longer pillars and smaller data line currents).

In this disclosure, a dedicated memory block is used for increasing the total data line current. Specifically, the dedicated memory block is controlled by a memory controller during sensing of a selected memory block of multiple memory blocks. The controller causes one or more regulators to drive the selected memory block such that a pillar current flows through the pillar of the memory block. The pillar current may be small, as described above. The controller may also cause regulators to drive a dedicated memory block to generate a sensing current. The sensing current may then be combined with the pillar current to form a total data line current. A sense amplifier thus senses the total data line current, which is much bigger than the pillar current. As a result, the data line settling time can be reduced and the sensing speed can be improved.

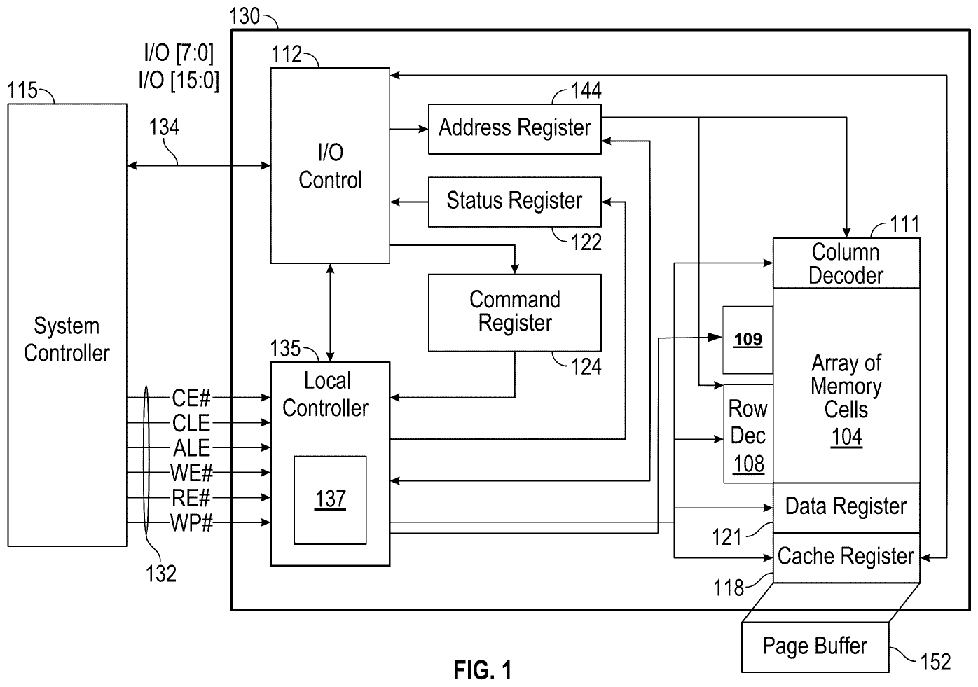

FIG. 1 is a simplified block diagram of a memory device 130 in communication with a system controller 115 of a memory system, according to an embodiment. A memory system may be or include any device or collection of devices, where the device or collection of devices includes at least one memory array. For example, a memory system may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other devices. A memory system may communicate with a host system, which may include a host system controller. The host system may be implemented using one or more processors and a memory system for writing data to the memory system, reading data from the memory system, erasing data, or refreshing data.

A memory system may include one or more memory devices, such as device 130. A memory device 130 may include one or more memory arrays of any type of memory cells (e.g., non-volatile memory cells, volatile memory cells, or any combination thereof). For example, memory device 130 may include NAND (e.g., NAND flash) memory, ROM, phase change memory (PCM), NOR (e.g., NOR flash) memory, etc. In some cases, memory device 130 is a NAND memory device 130, may include memory cells configured to each store one bit of information, which may be referred to as single level cells (SLCs). Additionally, or alternatively, a NAND memory device 130 may include memory cells configured to each store multiple bits of information, which may be referred to as multi-level cells (MLCs) if configured to each store two bits of information, as tri-level cells (TLCs) if configured to each store three bits of information, as quad-level cells (QLCs) if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

As shown in FIG. 1 and described below in more detail, memory device 130 includes an array of memory cells 104 logically arranged in rows and columns. Memory cells of a logical row are typically connected to the same access line (e.g., a word line) while memory cells of a logical column are typically selectively connected to the same data line (e.g., a bit line). A single access line can be associated with more than one logical row of memory cells and a single data line can be associated with more than one logical column. Memory cells (not shown in FIG. 1) of at least a portion of the array of memory cells 104 are capable of being programmed to one of at least two target data states for storing any number of bits of information.

With continued reference to FIG. 1, row decode circuitry 108 and column decode circuitry 111 are provided to decode address signals. Address signals are received and decoded to access the array of memory cells 104. Memory device 130 also includes input/output (I/O) control circuitry 112 to manage input of commands, addresses, and data to memory device 130 as well as output of data and status information from memory device 130. An address register 114 is in communication with I/O control circuitry 112 and row decode circuitry 108 and column decode circuitry 111 to latch the address signals prior to decoding. Row decode circuitry 108 and column decode circuitry 111 may simply be referred to as row decoder 108 and column decoder 111, respectively. A command register 124 is in communication with the I/O control circuitry 112 and local controller 135 to latch incoming commands.

A memory controller (e.g., the local controller 135 internal to memory device 130) controls access to the array of memory cells 104 in response to the commands and generates status information for the external system controller 115. For example, the local controller 135, on its own or in response to a command provided by external system controller 115, is configured to perform access operations (e.g., read operations, programming operations, and/or erase operations) on the array of memory cells 104. The local controller 135 is in communication with row decode circuitry 108 and column decode circuitry 111 to control the row decode circuitry 108 and column decode circuitry 111 according to the addresses. In some embodiments, local controller 135 may further include a bias generation control circuit 137 in communication with biasing generation circuit 109. Memory device 130 further includes a biasing generation circuit 109, which applies particular biasing voltages and currents to the access lines and data lines of the array of memory cells 104. The biasing generation circuit 109 may include one or more regulators controlled by the memory controller according to the addresses provided by the row decode circuitry 108 and column decode circuitry 111. For example, the one or more regulators may apply biasing voltages and/or currents to certain word lines and bit lines for selected memory cells to perform read, write, program, and erase operations. The biasing generation circuit 109 may include one or more circuits for generating biasing voltages and currents and for regulating or driving the word lines and bit lines of the selected memory cells. Examples of the biasing generation circuit 109 are described in more detail below.

In some embodiments, local controller 135 communicates with the external system controller 115, which may be a host controller (e.g., an UFS or eMMC controller, or a CPU communicating with local controller 135) located in a host system or a memory system controller located in a memory system. In some embodiments, local controller 135 is disposed on the same semiconductor die as the memory array (e.g., array 104), and a separate system controller 115 is disposed on a different die. In other examples, some portions of memory device 130 may be disposed on a first die and other portions of memory device 130 may be disposed on a second die different from the first die. For instance, the first die may include the array of memory cells 104 and its associated circuitry such as the column decoder 111 and row decoder 108, etc. The second die may include logic circuitry, power circuitry, or other circuitry of device 130. Thus, the second die may include system controller 115, I/O control 112, etc. In this example, the first die has no local controller, and the second die includes the system controller 115. The first die and the second die can be hybrid bonded together using, for example, through-hole vias (TSVs) such that they are electrically connected. The first die and the second die may also be wafer-bonded using flip-chip bonding technologies, etc. In this disclosure, a system controller 115 and a local controller 135 may both be referred to as memory controllers, or a first memory controller and a second memory controller, for simplicity. It is understood that while they may be different controllers, certain operations disclosed herein may be caused or performed by either or both memory controllers, unless otherwise specified.

Local controller 135 is also in communication with a cache register 118 and a data register 121. In some embodiments, one or more cache registers 118 can collectively form at least a part of a cache buffer. Cache register 118 latches or buffers data, either incoming or outgoing, as directed by local controller 135 to temporarily store data while the array of memory cells 104 is busy writing or reading, respectively, other data. During a program operation (e.g., write operation), data can be passed from cache register 118 to the data register 121 for transfer to the array of memory cells 104; then new data can be latched in cache register 118 from the I/O control circuitry 112. During a read operation, data can be passed from the cache register 118 to the I/O control circuitry 112 for output to the system controller 115; then new data can be passed from the data register 121 to cache register 118. In some embodiments, cache register 118 and/or the data register 121 can form at least a portion of a page buffer 152 of the memory device 130. The page buffer 152 can further include sensing devices such as a sense amplifier, to sense a data state of a memory cell of the array of memory cells 104, e.g., by sensing a state of a data line connected to that memory cell. A status register 122 can be in communication with I/O control circuitry 112 and the local memory controller 135 to latch the status information for output to system controller 115.

As shown in FIG. 1, memory device 130 receives various control signals via local controller 135 from system controller 115 over a control link 132. For example, the control signals can include a chip enable signal CE #, a command latch enable signal CLE, an address latch enable signal ALE, a write enable signal WE #, a read enable signal RE #, and a write protect signal WP #. Additional or alternative control signals (not shown) can be further received over control link 132 depending upon the nature of memory device 130. In one embodiment, memory device 130 receives command signals (which represent commands), address signals (which represent addresses), and data signals (which represent data) from the system controller 115 over a multiplexed input/output (I/O) bus 134 and outputs data to the system controller 115 over I/O bus 134.

For example, the commands can be received over input/output (I/O) pins [7:0] of I/O bus 134 at I/O control circuitry 112 and can then be written into a command register 124. The addresses can be received over input/output (I/O) pins [7:0] of I/O bus 134 at I/O control circuitry 112 and can then be written into address register 114. The data can be received over input/output (I/O) pins [7:0] for an 8-bit device or input/output (I/O) pins [15:0] for a 16-bit device at I/O control circuitry 112 and then can be written into cache register 118. The data can be subsequently written into data register 121 for programming the array of memory cells 104.

In an embodiment, cache register 118 can be omitted, and the data can be written directly into data register 121. Data can also be output over input/output (I/O) pins [7:0] for an 8-bit device or input/output (I/O) pins [15:0] for a 16-bit device. Although reference can be made to I/O pins, they can include any conductive node providing for electrical connection to the memory device 130 by an external device (e.g., the system controller 115), such as conductive pads or conductive bumps as are commonly used. While the above description using 16 bits I/O bus 134 as an example, it is understood that bus 134 can be configured to any number of bits (e.g., 64 bits).

It will be appreciated by those skilled in the art that additional circuitry and signals can be provided, and that memory device 130 of FIG. 1 has been simplified. It should be recognized that the functionality of the various block components described with reference to FIG. 1 may not necessarily be segregated to distinct components or component portions of an integrated circuit device. For example, a single component or component portion of an integrated circuit device could be adapted to perform the functionality of more than one block component of FIG. 1. Alternatively, one or more components or component portions of an integrated circuit device could be combined to perform the functionality of a single block component of FIG. 1. Additionally, while specific I/O pins are described in accordance with popular conventions for receipt and output of the various signals, it is noted that other combinations or numbers of I/O pins (or other I/O node structures) can be used in the various embodiments.

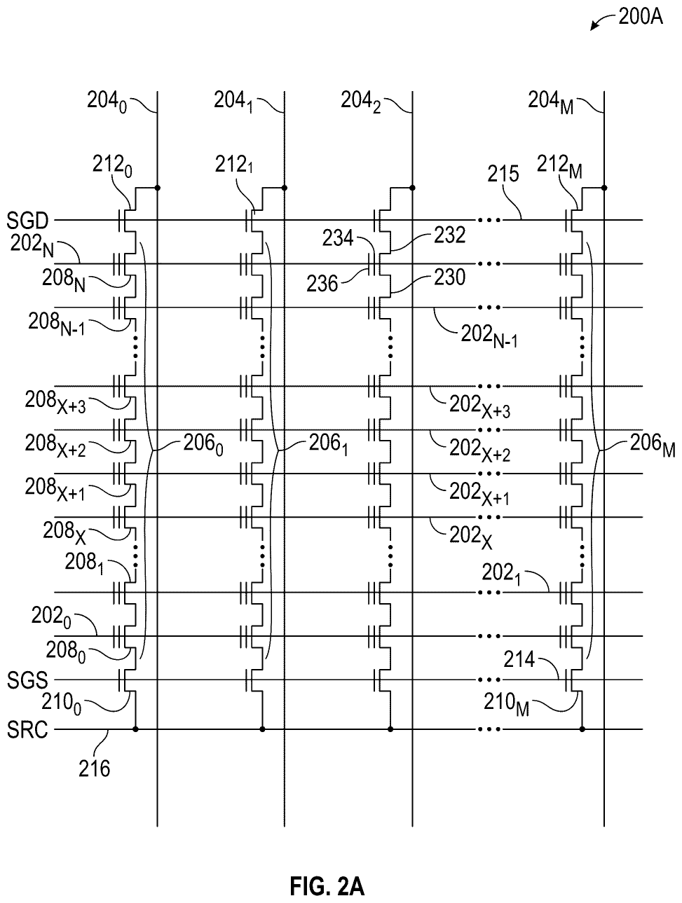

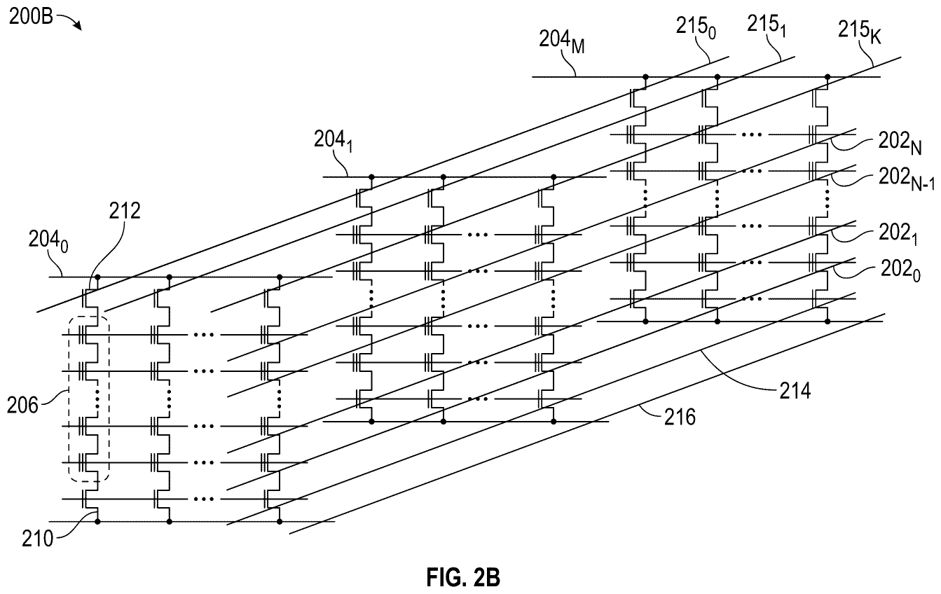

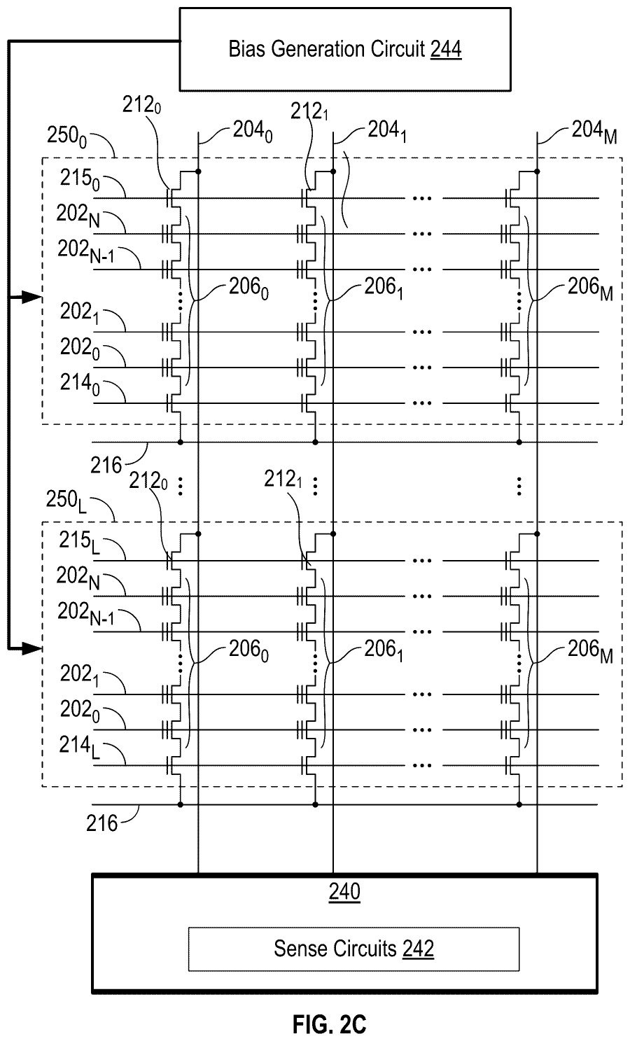

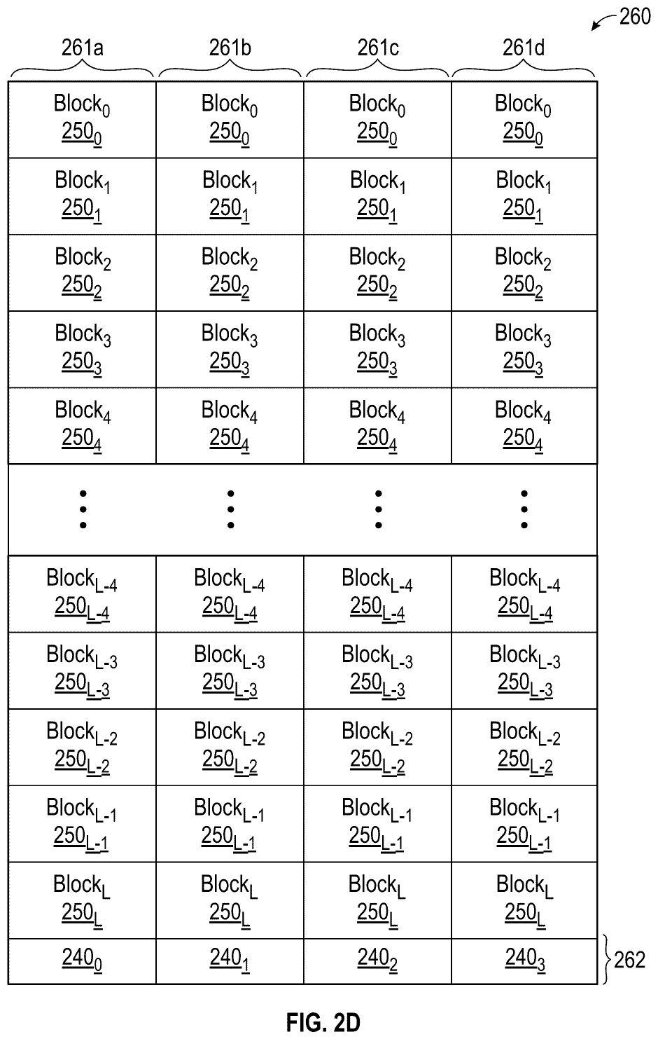

FIGS. 2A-2B are example schematics of portions of an array of memory cells 200A, such as a NAND memory array. Array of memory cells 200A may be an example of memory array 104 of a memory device 130 as described with reference to FIG. 1 according to an embodiment. Memory array 200A includes access lines, such as word lines 202₀ to 202_{N}, and data lines, such as bit lines 204₀ to 204_{M}. The word lines 202 can be connected to global access lines (e.g., global word lines), not shown in FIG. 2A, in a many-to-one relationship. For some embodiments, memory array 200A can be formed over a semiconductor that, for example, can be doped to have a conductive type, such as a p-type conductivity, e.g., to form a p-well, or an n-type conductivity, e.g., to form an n-well.

Memory array 200A can be arranged in rows (each corresponding to a word line 202) and columns (each corresponding to a bit line 204). Each column can include a string of series-connected memory cells (e.g., non-volatile memory cells), such as one of NAND strings 206₀ to 206_{M}. Each NAND string 206 can be connected (e.g., selectively connected) to a common source (SRC) 216 and can include memory cells 208₀ to 208_{N}. The memory cells 208 can represent non-volatile memory cells for storage of data. The memory cells 208 of each NAND string 206 can be connected in series between a select transistor 210 (e.g., a field-effect transistor), such as one of the select gates 210₀ to 210_{M} (e.g., that can be source select transistors, commonly referred to as select gate source), and a select transistor 212 (e.g., a field-effect transistor), such as one of the select transistors 212₀ to 212_{M} (e.g., that can be drain select transistors, commonly referred to as select gate drain). Select gates 210₀ to 210_{M} can be commonly connected to a select line 214, such as a source select line (SGS), and select transistors 212₀ to 212_{M} can be commonly connected to a select line 215, such as a drain select line (SGD). Although depicted as traditional field-effect transistors, the select transistors 210 and 212 can utilize a structure similar to (e.g., the same as) the memory cells 208. The select transistors 210 and 212 can represent a number of select gates connected in series, with each select transistor in series configured to receive a same or independent control signal.

A source of each select transistor 210 can be connected to common source 216. The drain of each select transistor 210 can be connected to a memory cell 208₀ of the corresponding NAND string 206. For example, the drain of select gate 210₀ can be connected to memory cell 208₀ of the corresponding NAND string 206₀. Therefore, each select transistor 210 can be configured to selectively connect a corresponding NAND string 206 to the common source 216. A control gate of each select transistor 210 can be connected to select line 214.

The drain of each select transistor 212 can be connected to bit line 204 for the corresponding NAND string 206. For example, the drain of select transistor 212₀ can be connected to the bit line 204₀ for the corresponding NAND string 206₀. The source of each select transistor 212 can be connected to a memory cell 208_{N} of the corresponding NAND string 206. For example, the source of select transistor 212₀ can be connected to memory cell 208_{N} of the corresponding NAND string 206₀. Therefore, each select transistor 212 can be configured to selectively connect a corresponding NAND string 206 to the corresponding bit line 204. A control gate of each select transistor 212 can be connected to select line 215.

The memory array 200A in FIG. 2A can be a quasi-two-dimensional memory array and can have a generally planar structure, e.g., where the common source 216, NAND strings 206 and bit lines 204 extend in substantially parallel planes. Alternatively, the memory array 200A in FIG. 2A can be a three-dimensional memory array, e.g., where NAND strings 206 can extend substantially perpendicular to a plane containing the common source 216 and to a plane containing the bit lines 204 that can be substantially parallel to the plane containing the common source 216.

Typical construction of memory cells 208 includes a data-storage structure 234 (e.g., a floating gate, charge trap, and the like) that can determine a data state of the memory cell (e.g., through changes in threshold voltage), and a control gate 236, as shown in FIG. 2A. The data-storage structure 234 can include both conductive and dielectric structures while the control gate 236 is generally formed of one or more conductive materials. In some cases, memory cells 208 can further have a defined source/drain (e.g., source) 230 and a defined source/drain (e.g., drain) 232. Memory cells 208 have their control gates 236 connected to (and in some cases form) a word line 202.

A column of the memory cells 208 can be a NAND string 206 or a number of NAND strings 206 selectively connected to a given bit line 204. A row of memory cells 208 can be memory cells 208 commonly connected to a given word line 202. A row of memory cells 208 can, but need not, include all the memory cells 208 commonly connected to a given word line 202. Rows of memory cells 208 can often be divided into one or more groups of physical pages of memory cells 208, and physical pages of the memory cells 208 often include every other memory cell 208 commonly connected to a given word line 202. For example, the memory cells 208 commonly connected to word line 202_{N} and selectively connected to even bit lines 204 (e.g., bit lines 204₀, 204₂, 204₄, etc.) can be one physical page of the memory cells 208 (e.g., even memory cells) while memory cells 208 commonly connected to word line 202_{N} and selectively connected to odd bit lines 204 (e.g., bit lines 204₁, 204₃, 204₅, etc.) can be another physical page of the memory cells 208 (e.g., odd memory cells).

Although bit lines 204₃-204₅ are not explicitly depicted in FIG. 2A, it is apparent from the figure that the bit lines 204 of the array of memory cells 200A can be numbered consecutively from bit line 204₀ to bit line 204_{M}. Other groupings of memory cells 208 commonly connected to a given word line 202 can also define a physical page of memory cells 208. For certain memory devices, all memory cells commonly connected to a given word line can be deemed a physical page of memory cells. The portion of a physical page of memory cells (which, in some embodiments, could still be the entire row) that is read during a single read operation or programmed during a single programming operation (e.g., an upper or lower page of memory cells) can be deemed a logical page of memory cells. A block of memory cells can include those memory cells that are configured to be erased together, such as all memory cells connected to word lines 202₀-202_{N} (e.g., all NAND strings 206 sharing common word lines 202). Unless expressly distinguished, a reference to a page of memory cells herein refers to the memory cells of a logical page of memory cells. A logical page may or may not be the same as a physical page. Although the example of FIG. 2A is discussed in conjunction with NAND flash, the embodiments and concepts described herein are not limited to a particular array architecture or structure, and can include other structures (e.g., SONOS, phase change, ferroelectric, etc.) and other architectures (e.g., AND arrays, NOR arrays, etc.).

FIG. 2B is another schematic of a portion of an array of memory cells 200B as could be used in a memory device 130, e.g., as a portion of the array of memory cells 104. Like numbered elements in FIG. 2B correspond to the description as provided with respect to FIG. 2A. FIG. 2B provides additional detail of one example of a three-dimensional NAND memory array structure. Three-dimensional NAND memory array 200B can incorporate vertical structures which can include semiconductor pillars where a portion of a pillar can act as a channel region of the memory cells of NAND strings 206. NAND strings 206 can be each selectively connected to a bit line 204₀-204_{M} by a select transistor 212 (e.g., that can be drain select transistors, commonly referred to as select gate drain) and to a common source 216 by a select transistor 210 (e.g., that can be source select transistors, commonly referred to as select gate source). Multiple NAND strings 206 can be selectively connected to the same bit line 204. Subsets of NAND strings 206 can be connected to their respective bit lines 204 by biasing the select lines 215₀-215_{K} to selectively activate particular select transistors 212 each between a NAND string 206 and a bit line 204. The select transistors 210 can be activated by biasing the select line 214. In some embodiments, each sub-block or string of memory cells has a separate select line 214 from other sub-blocks or strings. In some embodiments, a pair of sub-blocks shares a select line 214. Each word line 202 can be connected to multiple rows of memory cells of the memory array 200B. Rows of memory cells that are commonly connected to each other by a particular word line 202 can collectively be referred to as tiers.

The three-dimensional NAND memory array 200B may include multiple stacked layers of levels of memory cells and connected using vertical channels such as semiconductor pillars. The number of layers in three-dimensional NAND memory array 200B can be, for example, 32, 48, 64, 96, 112 layers, or any number of layers. In some examples, a group of layers may be collectively referred to as a deck. A deck in a three-dimensional NAND memory array may be processed together (e.g., etched together for forming a portion of the semiconductor pillar). A memory device having three-dimensional NAND memory arrays can provide more memory cells on a single chip than a memory device formed by two-dimensional NAND arrays; and therefore provide a higher storage capacity. Furthermore, in a memory device having three-dimensional NAND memory arrays, transistors in memory cells are spaced out, and therefore interference and electron leaks can be reduced.

In some examples, memory cells can be grouped into memory blocks. FIG. 2C depicts groupings of NAND strings 206 into blocks of memory cells 250, e.g., blocks of memory cells 250₀-250_{L}. Blocks of memory cells 250 can be groupings of memory cells 208 that can be erased together in a single erase operation. The group of memory cells that can be erased together is also referred to as an erase block. Each block of memory cells 250 can represent those NAND strings 206 commonly associated with a single select line 215, e.g., select line 215₀. The common source 216 for the block of memory cells 250₀ can be a same source as the source 216 for the block of memory cells 250_{L}. For example, each block of memory cells 250₀-250_{L} can be commonly or selectively connected to the source 216. Word lines 202 and select lines 214 and 215 of one block of memory cells 250 can have no direct connection to word lines 202 and select lines 214 and 215, respectively, of any other block of memory cells of the blocks of memory cells 250₀-250_{L}. In some examples, a block of memory cells can be generally understood to include four or more sub-blocks, wherein each sub-block includes a separate string of memory cells. Thus, in FIG. 2C, a first sub-block may include a string 206₀, a second sub-block may include a string 206₁, and so forth.

In some embodiments, the select lines 215₀-215_{L} and access lines 202 are driven by bias generation circuit 244. Bias generation circuit 244 may include circuits and/or regulators for generating biasing voltages and/or currents for the memory blocks 250₀-250_{L}, such that the operational points of the memory cells are set for certain memory operations (e.g., read, program, etc.). In one example, bias generation circuit 244 is a part of circuit 109. For example, if a memory cell in the string 206₁ is selected for a read operation, the bias generation circuit 244 can be controlled (e.g., by controller 115 or 135) to apply particular biasing voltages to the select line 215₀ and word lines 202. For instance, bias generation circuit 244 applies a particular voltage or voltages to the word line 202 connected to the selected memory cell in the string 206₁, such that the threshold voltage of the selected memory cell can be sensed for performing a reading operation. Because all memory cells in the string 206₁ are connected to the same bit line 204₁, bias generation circuit 244 applies a passing voltage (e.g., a sufficiently high voltage) to other unselected memory cells in the same string 206₁, such that the other memory cells in the same string 206₁ are turned on and the current flowing through the selected memory cell can be sensed via by sensing the current of bit line 204₁. In some examples described below in more detail, bias generation circuit 244 also applies a particular voltage or voltages to a dedicated memory block controllable to generate a sensing current for increasing the bit line current. During a sensing operation (e.g., a read operation), the current of the bit line 204₁ is sensed to determine the data value stored in the selected memory cell. Increasing the bit line current reduces the data line settling time, and therefore increases the sensing speed. As a result, the speed of the sensing operation (e.g., read, program verification, etc.) is improved.

With continued reference to FIG. 2C, the bit lines 204₀-204_{M} can be connected (e.g., selectively connected) to a buffer portion 240, which can be a portion of the page buffer 152 of the memory device 130. The buffer portion 240 can correspond to a memory plane (e.g., the set of blocks of memory cells 250₀-250_{L}). The buffer portion 240 can include sense circuits 242 (which can include sense amplifiers) for sensing the data line current (e.g., the current flowing through a bit line 204), thereby sensing the data values indicated on respective bit lines 204. In one example, buffer portion 240 can be a part of page buffer 152. As described below, multiple buffer portions 240 may collectively form a page buffer 152.

FIG. 2D is a block schematic of a portion of an example array of memory cells 260. Array of memory cells 260 can be used as array 104 in a memory device 130. The array of memory cells 260 is depicted as having four memory planes 261 (e.g., memory planes 261a-261d). Each of the memory planes 261 may refer to a group of memory blocks of memory cells 250. Each memory plane 261 can be in communication with a respective buffer portion 240, which can collectively form a page buffer 262. Page buffer 262 may be used to implement page buffer 152 shown in FIG. 1. While four memory planes 261 are depicted, other numbers of memory planes 261 can be commonly in communication with a page buffer 262. Each memory plane 261 is depicted to include L+1 blocks of memory cells 250 (e.g., blocks of memory cells 250₀-250_{L}).

In some cases, concurrent operations may be performed on different planes. For example, concurrent operations may be performed on memory cells within different blocks 250 so long as the different blocks 250 are in different planes 261. In some cases, an individual memory block 250 may be referred to as a physical block, and a virtual block may refer to a group of blocks 250 within which concurrent operations may occur. For example, concurrent operations may be performed on four blocks of 250₀ that are within planes 261a, 261b, 261c, and 261d, respectively, and the four blocks of 250₀ may be collectively referred to as a virtual block. In some cases, a virtual block may include blocks from different memory devices. In some cases, the physical blocks within a virtual block may have the same block address within their respective planes. In some cases, performing concurrent operations in different planes 261 may be subject to one or more restrictions, such as concurrent operations being performed on memory cells within different pages that have the same page address within their respective planes 261 (e.g., related to command decoding, page address decoding circuitry, or other circuitry being shared across planes 261).

In some cases, a block 250 may include memory cells organized into rows (pages) and columns (e.g., strings, not shown). For example, memory cells in a same page may share (e.g., be coupled with) a common word line, and memory cells in a same string may share (e.g., be coupled with) a common digit line (which may alternatively be referred to as a bit line).

For some NAND architectures, memory cells may be read and programmed (e.g., written) at a first level of granularity (e.g., at a page level of granularity, or portion thereof) but may be erased at a second level of granularity (e.g., at a block level of granularity). That is, a page may be the smallest unit of memory (e.g., set of memory cells) that may be independently programmed or read (e.g., programed or read concurrently as part of a single program or read operation), and a memory block 170 may be the smallest unit of memory (e.g., set of memory cells) that may be independently erased (e.g., erased concurrently as part of a single erase operation). Further, in some cases, NAND memory cells may be erased before they can be re-written with new data. Thus, for example, a used page may, in some cases, not be updated until the entire block that includes the page has been erased.

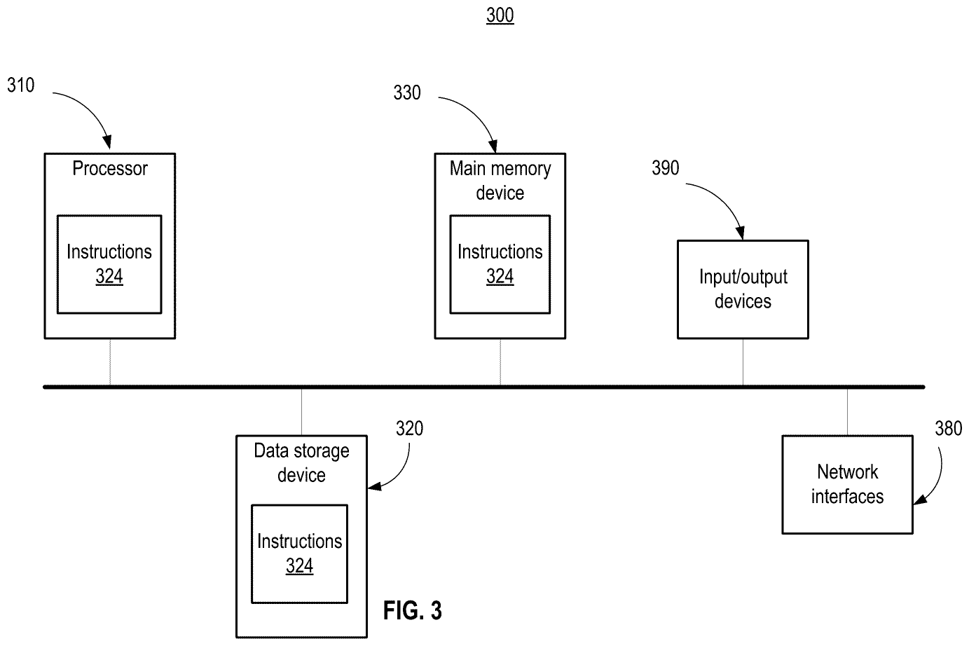

A high-level block diagram of an example apparatus 300 that may be used to implement systems, apparatus, and methods described herein is illustrated in FIG. 3. It is understood that various systems, apparatus, and methods described herein may be implemented using analog and/or digital circuitry, or using one or more computers using well-known computer processors, memory systems, storage devices, computer software, and other components. Typically, a computer includes a processor for executing instructions and one or more memory systems for storing instructions and data. A computer may also include, or be coupled to, one or more mass storage devices, such as one or more magnetic disks, internal hard disks and removable disks, magneto-optical disks, optical disks, etc.

Various systems, apparatus, and methods described herein may be implemented using computers operating in a client-server relationship. Typically, in such a system, the client computers are located remotely from the server computers and interact via a network. The client-server relationship may be defined and controlled by computer programs running on the respective client and server computers. Examples of client computers can include desktop computers, workstations, portable computers, cellular smartphones, tablets, or other types of computing devices.

Various systems, apparatus, and methods described herein may be implemented using a computer program product tangibly embodied in an information carrier, e.g., in a non-transitory machine-readable storage device, for execution by a programmable processor; and the method processes and steps described herein, including one or more of the steps of at least some of the FIGS. 1-8, may be implemented using one or more computer programs that are executable by such a processor. A computer program is a set of computer program instructions that can be used, directly or indirectly, in a computer to perform a certain activity or bring about a certain result. A computer program can be written in any form of programming language, including compiled or interpreted languages, and it can be deployed in any form, including as a stand-alone program or as a module, component, subroutine, or other unit suitable for use in a computing environment.

As shown in FIG. 3, apparatus 300 may be used to implement a host system that includes, is coupled to, or utilizes a memory system (e.g., memory system shown in FIG. 1). Apparatus 300 can be used to perform operations of a controller (e.g., to execute an operating system to perform operations corresponding to system controller 115 and/or local controller 135 of FIG. 1).

In some embodiments, apparatus 300 comprises a processor 310 operatively coupled to a data storage device 320 and a main memory device 330. Processor 310 controls the overall operation of apparatus 300 by executing computer program instructions 324 that define such operations. The instructions 324 include instructions to implement functionality of a controller (e.g., system controller 115 and/or local controller 135 of FIG. 1). The computer program instructions 324 may be stored in data storage device 320, or other computer-readable medium, and loaded into main memory device 330 when execution of the computer program instructions is desired. For example, processor 310 may be used to implement one or more components and systems described herein, such as system controller 115 and/or local controller 135 (shown in FIG. 1). Thus, the method steps of at least some of FIGS. 1-8 can be defined by the computer program instructions 324 stored in main memory device 330 and/or data storage device 320 and controlled by processor 310 executing the computer program instructions 324. For example, the computer program instructions 324 can be implemented as computer executable code programmed by one skilled in the art to perform an algorithm defined by the method steps discussed herein in connection with at least some of FIGS. 1-8. Accordingly, by executing the computer program instructions, processor 310 executes an algorithm defined by the method steps of these aforementioned figures to perform operations (e.g., read, program, erase, etc.). Apparatus 300 also includes one or more network interfaces 380 for communicating with other devices via a network. Apparatus 300 may also include one or more input/output devices 390 that enable user interaction with apparatus 300 (e.g., display, keyboard, mouse, speakers, buttons, etc.).

Processor 310 may include both general and special purpose microprocessors and may be the sole processor or one of multiple processors of apparatus 300. Processor 310 may comprise one or more central processing units (CPUs), and one or more graphics processing units (GPUs), which, for example, may work separately from and/or multi-task with one or more CPUs to accelerate processing, e.g., for various image processing applications described herein. Processor 310, data storage device 320, and/or main memory device 330 may include, be supplemented by, or incorporated in, one or more application-specific integrated circuits (ASICs) and/or one or more field programmable gate arrays (FPGAs).

Data storage device 320 and main memory device 330 each comprise a tangible non-transitory computer readable storage medium. Data storage device 320, and main memory device 330, may each include high-speed random access memory, such as dynamic random access memory (DRAM), static random access memory (SRAM), double data rate synchronous dynamic random access memory (DDR RAM), or other random access solid state memory devices, and may include non-volatile memory, such as one or more magnetic disk storage devices such as internal hard disks and removable disks, magneto-optical disk storage devices, optical disk storage devices, flash memory devices (NAND memory devices, NOR memory devices), semiconductor memory devices, such as erasable programmable read-only memory (EPROM), electrically erasable programmable read-only memory (EEPROM), compact disc read-only memory (CD-ROM), digital versatile disc read-only memory (DVD-ROM) disks, or other non-volatile solid state storage devices. For example, data storage device 320 may be implemented using the memory system (e.g., system shown in FIG. 1) described herein. In some examples, data storage device 320 and main memory device 330 may include one or more memory devices 130 (FIG. 1).

Input/output devices 390 may include peripherals, such as a printer, scanner, display screen, etc. For example, input/output devices 390 may include a display device such as a cathode ray tube (CRT), plasma or liquid crystal display (LCD) monitor for displaying information to a user, a keyboard, and a pointing device such as a mouse or a trackball by which the user can provide input to apparatus 300.

Any or all of the functions of the systems and apparatuses discussed herein may be performed by processor 310, and/or incorporated in, an apparatus or a system such as system 100. Further, system 100 and/or apparatus 300 may utilize one or more neural networks or other deep-learning techniques performed by processor 310 or other systems or apparatuses discussed herein.

One skilled in the art will recognize that an implementation of an actual computer or computer system may have other structures and may contain other components as well, and that FIG. 3 is a high-level representation of some of the components of such a computer for illustrative purposes.

FIGS. 4A-4B show a side view (e.g., a cross section with respect to the X-Z directions) of a portion of the three-dimensional structure of memory device 130 including a structure of memory cell string 231 (e.g., a NAND string) having one or more pillars, according to some embodiments described herein. FIG. 4A shows the structure of one memory cell string (e.g., memory cell string 231) of memory device 130. However, other memory cell strings (e.g., NAND strings 206₀-206_{M} in FIG. 2A and NAND strings 206 in FIG. 2B) can have a similar or the same structure as memory cell string 231 shown in FIG. 4A.

Starting from the top of FIG. 4A, memory device 130 have data lines 401 and 402 (e.g., corresponding to bit lines 204 in FIGS. 2A, 2B, and 2C) coupled to conductive structures 431 and 432, respectively, and coupled to conductive contacts 411 and 412, respectively. Data lines 401 and 402 are therefore electrically connected to pillars 441 and 442, respectively, via the conductive contacts 411 and 412, respectively. It is understood that memory device 130 can include many other similar data lines, conductive structures, and conductive contacts, which are not shown for simplicity.

FIGS. 4A-4B shows directions X, Y, and Z that can be relative to the physical directions (e.g., dimensions) of the structure of memory device 130. For example, the Z-direction can be a direction perpendicular to (e.g., vertical direction relative to) a substrate (e.g., a semiconductor substrate) of memory device 130. The Z-direction is perpendicular to the X-direction and Y-direction (e.g., the Z-direction is perpendicular to an X-Y plane of memory device 130).

As shown in FIG. 4A, data lines 401 and 402 can carry signals (e.g., bit line signals) BL1 and BL2, respectively. In the physical structure of memory device 130, data lines 401 and 402 can be structured as conductive lines and have respective lengths extending in the Y-direction. The data lines (e.g., data lines 401 and 402) of memory device 130 can be formed on different levels (e.g., layers) in the physical structure of memory device 130. For example, data lines 401 can be formed on one level (e.g., a lower level 461) of memory device 130, and data lines 402 can be formed on another level (e.g., an upper level 462) of memory device 130. Although not shown in FIG. 4A, multiple data lines can be located side-by-side in any particular level. For example, level 461 may have multiple data lines and level 462 may also have multiple data lines. Data lines in the same level can be separated from each other by a distance (e.g., a gap) in the X-direction. The gaps between data lines in the same level may be the same or different. As shown in FIG. 4A, each of data lines 401 and 402 can have a thickness in the Z-direction and a width in the X-direction. Each of the thickness (in the Z-direction) and the width (in the X-direction) is less than the length (in the Y-direction). The thickness can be less than, equal to, or greater than the width.

In FIG. 4A, each of conductive structures 431 and 432 can have a length extending in the Z-direction. In some examples, the length of conductive structure 431 can be less than the length of conductive structure 432, because level 461 is a lower level that is located closer to memory array 201. Each of conductive structures 431-432 can include (e.g., can be formed from) a conductive material that extends in the Z-direction. Examples of the conductive material include metal, alloy, conductively doped polysilicon, or other conductive materials. Although not shown in FIG. 4A, memory device 130 can include a dielectric material (e.g., silicon dioxide) formed between levels 462 and 461. The dielectric material can be formed before conductive structures 431 and 432. Then, openings (e.g., holes (e.g., vertical vias)) can be formed in the dielectric material. The material of each of conductive structures 431-432 can be formed (e.g., deposited) inside a respective opening of the openings.

As shown in FIG. 4A, each of conductive structures 431 and 432 can be coupled to (e.g., in electrical contact with) a respective conductive contact among conductive contacts 411 and 412 and coupled to (e.g., in electrical contact with) a respective data line among data lines 401 and 402. For example, conductive structure 431 can include an end (e.g., bottom end) coupled to (e.g., directly contacting) conductive contact 411, and another end (e.g., top end) coupled to (e.g., directly contacting) data line 401. In another example, conductive structure 432 can include an end (e.g., bottom end) coupled to (e.g., directly contacting) conductive contact 412, and another end (e.g., top end) coupled to (e.g., directly contacting) data line 402.

As shown in FIG. 4A, memory cell string 231 can include pillars (e.g., vertical pillars) 441 and 442. Pillars 441 and 442 can include pillar contacts 441C and 442C, respectively, located on the same level (e.g., level 459) of memory device 130. Pillars 441 and 442 can be located under (e.g., directly under) respective conductive contacts 411 and 412, which are under (e.g., directly under) respective conductive structures 431 and 432. Conductive structures 431 and 432 can be coupled to (e.g., in electrical contact with) pillars 441 and 442, respectively, through conductive contacts 411 and 412, respectively. Thus, as shown in FIG. 4A, data lines 401 and 402 can be coupled to (e.g., electrically coupled to) pillars 441 and 442, respectively, through respective conductive structures 431 and 432 and respective conductive contacts 411 and 412.

As described above, data lines 401 and 402 are located in levels 461 and 462, respectively. Levels 461 and 462 are in portion of memory device 130 that is located above memory array 201 in the Z-direction. Memory array 201 is located above a substrate 490 of memory device 130 in the Z-direction. As described above, a memory array such as memory array 201 comprises multiple memory cell strings (one of which is shown as memory cell string 231).

As shown in FIG. 4A, pillar (e.g., a vertical pillar) 441 can be a part of memory cell string 231 and can have a length extending in the Z-direction (e.g., extend vertically with respect to substrate 490). Pillar 441 can extend through memory cells 208₀, 208₁, 208₂, and 208₃ of memory cell string 231. Pillar 441 can include (e.g., can be formed from) a conductive material (e.g., conductively doped polysilicon). Each of memory cells 208₀, 208₁, 208₂, and 208₃ can include a structure of transistor (e.g., a memory cell transistor). Part of pillar 441 can form the channel region (e.g., to conduct current) of the transistor of each memory cells 208₀, 208₁, 208₂, and 208₃. It is understood that while FIG. 4A only shows four memory cells 208₀-208₃, memory cell string 231 can include any number of memory cells that share a same pillar (e.g., pillar 441).

As described above, pillar contact 441C can be formed from conductively doped polysilicon, metal, or other conductive materials. Pillar 441 can include a portion 444. Pillar contact 441C and portion 444 of pillar 441 can include the same conductive material or different conductive materials. Conductive structure 431, conductive contact 411, and pillar 441 can be part of a circuit path (e.g., a conductive channel of memory cell string 231) between data line 401 and a conductive region 498 (associated with an SRC line). Conductive region 498 can be a part of a common source line (e.g., common source line or source plate 216 in FIG. 2A). Conductive structure 431 and pillar 441 can have the same material or different materials. In FIG. 4A, during a memory operation (e.g., read or write operation) of memory device 130, a circuit path (e.g., a current path) can be formed between data line 401 and conductive region 498 through conductive structure 431, conductive contact 411, and pillar 441 (which includes pillar contact 441C and portion 444 of pillar 441).

Substrate 490 of memory device 130 can include a semiconductor substrate (e.g., silicon-based substrate). For example, substrate 490 can include a p-type silicon substrate or an n-type silicon substrate. As shown in FIG. 4A, memory cells 208₀, 208₁, 208₂, and 208₃ of memory cell string 231 can be located along (e.g., adjacent) respective portions of pillar 441 in different levels (in the Z-direction) of memory device 130. For example, memory cells 208₀, 208₁, 208₂, and 208₃ can be located one over another (e.g., formed vertically) in levels 470, 471, 472, and 473, respectively, of memory device 130. Memory cells of other memory cell strings of memory device 130 can also be located on respective levels 470, 471, 472, and 473.

By stacking the memory cells in different levels, the memory device forms a 3D structure that has a higher capacity than a 2D device. In a typical 3D memory device (e.g., device 130 shown in FIG. 4A), for example, multiple levels (e.g., levels 470, 471, 472, and 473) are stacked together with one or more memory pillars (e.g., pillars 441 and 442) disposed vertically in the middle. The memory pillars may act as the channel region of the memory device. The multiple levels (e.g., layers or tiers) of the memory device may form groups or decks. A deck of a 3D memory device may be processed together (e.g., patterned and/or etched together) when forming the memory pillar associated thereof. A level of the memory device may have one or more access lines (e.g., word lines) or access line groups (e.g., word line groups). Each deck may have one or more access line segments (e.g., word line segments). An access line segment may have fewer or more access lines than those in a deck. For example, a deck may have two word line segments distributed in one or more levels. In some cases, certain memory operations (e.g., an erase operation) can be performed to a word line group (e.g., a deck), and not to the entire memory block. By not performing an operation to the entire memory block, the particular operation may be performed faster.

FIG. 4A further illustrates that access lines 450, 451, 452, and 453 of memory device 130 can be located along (e.g., adjacent) respective portions (in the Z-direction) of pillar 441 in the same levels (e.g., levels 470, 471, 472, and 473, respectively) that memory cells 208₀, 208₁, 208₂, and 208₃ are located. Access lines can include, for examples, word lines or control gates. Access lines 450, 451, 452, and 453 can include (e.g., can be formed from) a conductive material (or materials). Example materials for access lines 450, 451, 452, and 453 include metal, alloy, doped polysilicon, other conductive materials.

In FIG. 4A, a select line (e.g., drain select gate or SGD) 481 can have a length extending in the X-direction (e.g., perpendicular to the lengths (in the Y-direction) of data lines 401 and 402). The materials of select line 481 can include a conductive material (e.g., conductively doped polysilicon, metal, other conductive material). FIG. 4A shows an example where another select line (e.g., source select gate or SGS) 480 can have a structure (e.g., shape, material, or both) similar to (or the same as) that of select line 481. In some examples, select line 480 can have a structure (e.g., shape, material, or both) similar to (or the same as) that of each of access lines 450, 451, 452, and 453.

As shown in FIG. 4A, a transistor (e.g., source select transistor) 465 and a transistor (e.g., drain select transistor) 463 can be located along (e.g., adjacent) respective portions of pillar 441 in the Z-direction. Memory cells 208₀, 208₁, 208₂, and 208₃ of memory cell string 231 can be located along the portion of pillar 441 that is between transistors 465 and 463.

Memory cell string 231 can include materials 403, 404, and 405 formed between portion 444 of pillar 441 and a respective access line among access lines 450, 451, 452, and 453. Material 403 can also be formed between pillar 441 and each of select lines 480 and 481. Materials 403, 404, and 405 located at a particular memory cell (among memory cells 208₀, 208₁, 208₂, and 208₃) can be a part (e.g., a memory element) of that particular memory cell. As shown in FIG. 4A, the combination of materials 403, 404, and 405 of a memory cell (among memory cells 208₀, 208₁, 208₂, and 208₃) can be separated from (in the Z-direction) the combination of materials 403, 404, and 405 of another memory cell (among memory cells 208₀, 208₁, 208₂, and 208₃).

Material 403 can include a charge blocking material (or charge blocking materials), for example, a dielectric material (e.g., silicon nitride) that is capable of blocking a tunneling of a charge. Material 404 can include a charge storage material (or charge storage materials) that can provide a charge storage function to represent a value of information stored in memory cells 208₀, 208₁, 208₂, and 208₃. For example, material 404 can include polysilicon (e.g., conductively doped polysilicon), which can be either a p-type polysilicon or an n-type polysilicon. The polysilicon can be configured to operate as a floating gate (e.g., to store charge) in a memory cell (e.g., a memory cell 208₀, 208₁, 208₂, and 208₃). In another example, material 404 can include a dielectric material (e.g., silicon-nitride based material or other dielectric materials) that can trap charge in a memory cell (e.g., a memory cell 208₀, 208₁, 208₂, and 208₃). Material 405 can include a tunnel dielectric material (or tunnel dielectric materials), for example, silicon dioxide, that is capable of allowing tunneling of a charge (e.g., electrons).

As shown in FIG. 4A, memory device 130 can include circuitry 495 located (e.g., formed) under memory array 201 (e.g., located directly under memory cell string 231). Circuitry 495 can include circuit elements (e.g., transistors T) coupled to other circuit elements (e.g., coupled to data lines 401-402) of memory device 130. The circuit elements (e.g., transistors T) of circuitry 495 can be configured to perform part of a function of a memory device (e.g., memory device 130). For example, circuitry 495 can include decoder circuits, driver circuits, buffers (e.g., page buffers), sense amplifiers, charge pumps, and other circuitry of memory device 130. In one example, circuitry 495 includes sense circuits 242 shown in FIG. 2A. In an alternative structure of memory device 130, circuitry 495 can be located (e.g., formed) above memory array 201 (instead of under memory array 201). For example, in the alternative structure of memory device 130, circuitry 495 can be located above memory array 201 and under data lines 401 and 402, or located between data lines 401 and 402 of memory array 201 in the Z-direction. In another example, in the alternative structure of memory device 130, circuitry 495 can be located above memory array 201 and above data lines 401 and 402 in the Z-direction.

A different view of pillar 441 along a cross-sectional line 4B-4B is shown in FIG. 4B. FIG. 4B shows a top view (e.g., a cross section with respect to the X-Y plan) of portion 444 of pillar 441 along line 4B-4B of FIG. 4A. As shown in FIG. 4B, portion 444 of pillar 441 can include material 444A and material 444B surrounded by material 444A. Material 444A can be (or can include) a part of a conductive structure (e.g., a conductive channel) of pillar 441. Material 444B can include a dielectric material. In an alternative structure of pillar 441, material 444B can be omitted from pillar 441, such that the entire portion 444 of pillar 441 can include material 444A (without material 444B).

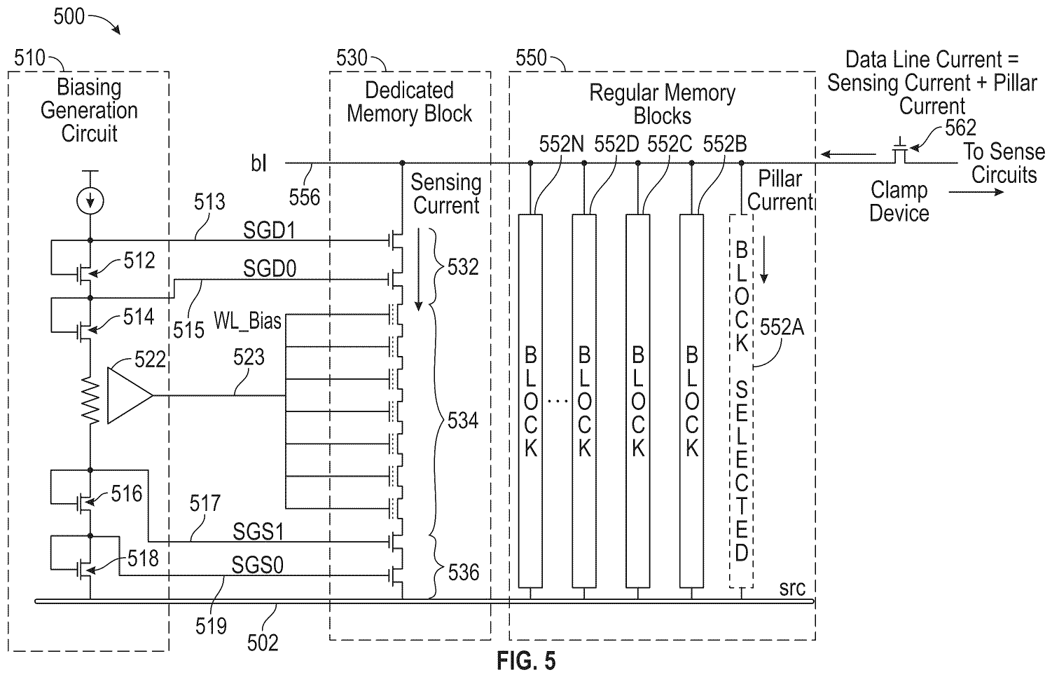

FIG. 5 illustrates an example memory device 500 with improved data line current-sensing speed in accordance with examples as disclosed herein. Memory device 500 shown in FIG. 5 can be memory device 130 described above in connection with FIGS. 1 and 2A-2D, but is simplified for illustration. As shown in FIG. 5, memory device 500 includes a biasing generation circuit 510, a dedicated memory block 530, and a plurality of memory blocks 550. The plurality of memory blocks 550 comprises memory blocks 552A, 552B, 552C, 552D, . . . and 552N (collectively as memory blocks 552). Multiple sub-blocks from different memory blocks 552 may be connected to a data line 556. As described above, a sub-block in a memory block may include a string of memory cells that are all connected to a common data line. Thus, multiple sub-blocks in a memory block may be connected to multiple data lines. For simplicity, only one data line 556 is shown in FIG. 5. Data line 556 may be a bit line. It is understood that other sub-blocks or strings of memory cells of the memory blocks 552 may be connected to other data lines. This is illustrated more clearly in FIGS. 2B and 2C, which shows that strings 206₀ of multiple memory blocks 250₀-250_{L} are connected to a same bit line 204₀ via select transistor 212₀; strings 206₁ of multiple memory blocks 250₀-250_{L} are connected to a same bit line 204₁ via select transistor 212₁; and so forth. For purposes of illustration, FIG. 5 only shows that multiple memory blocks 552 are connected to data line 556, but they can also be connected to other data lines (not shown). Also, it is understood that the current of data line 556 referred to herein may be the current of a memory cell string or a sub-block within a selected memory block (e.g., block 552A), but not the current of the entire memory block.

As shown in FIG. 5, during sensing operations (e.g., a read operation, a program verification operation, etc.) performed by the memory device 500, a memory cell in a block is selected. FIG. 5 shows that, for example, block 552A is selected. A selected memory block means that one or more memory cells in this block are selected for performing operations. A block may be selected by applying a particular biasing voltage to a select line of a memory cell string. Using FIG. 2C as illustration, block 250₀ is selected when the select line 215₀ is biased in a particular way (e.g., applying a voltage to activate the select transistors 212₀ located between a string 206₀ and a bit line 204₀.

With reference back to FIG. 5, during a sensing operation, the selected memory cell within block 552A is driven by one or more regulators (not shown in FIG. 5) for reading the data stored therein, and the other memory cells within block 552A may be applied a passing voltage. As a result, an electrical current flow through the pillar shared between the memory cells of a string or a subblock in memory block 552A. The current is sensed as the current of the data line 556 by a sense circuit (e.g., circuits 242 in FIG. 2C). For simplicity, such a current is referred to as a pillar current or a pillar current flowing through a memory block. It is understood that there may be other pillar currents flowing through other strings or subblocks of the same memory block, while these pillar currents flow through different data lines. These pillar currents may also be sensed by different sense circuits. However, as described above, because the memory device 500 may be a 3D device that has many layers stacked together, the vertical dimension of the pillar increases. In turn, the pillar resistance may increase significantly, and therefore, the pillar current flowing through the pillar of the selected memory block may decrease significantly, resulting in slower data line settling time.

FIG. 5 illustrates a dedicated memory block 530 that is configured to generate sensing current for increasing the overall data line current and therefore reducing the data line settling time. In one embodiment, dedicated memory block 530 may have the same or substantially the same components or sub-blocks as other memory blocks for storing data (e.g., memory blocks 552A-552N described above). Dedicated memory block 530 may comprise, for example, the same floating gate transistors, select transistors, access lines (e.g., word lines), select lines, etc. as a memory block shown in FIGS. 2A-2D. FIG. 5 only shows one column of the dedicated memory block 530. The column shown in FIG. 5 includes select transistors 532 and select transistors 536, and a string 534 of series-connected memory cells (e.g., a NAND string). The string 534 is connected in series between select transistors 532 and select transistors 536. Select transistors 532 and 536 are shown as each having two transistors connected in series. Each of the two transistors in select transistors 532 and 536 can be substantially the same as or similar to select transistors 212 and 210, respectively, described above. Select transistors 532 and 536 can represent a number of select gates connected in series, with each transistor in series configured to receive a same or independent control signal. Because the dedicated memory block 530 is used for generating sensing current, not for storing data, both the select transistors 532 and 536 can be controlled to turn on during the sensing operation for sensing the current of data line 556. For instance, biasing generation circuit 510 may provide particular biasing voltages to the drain select lines 515 and 513 (SGD0 and SGD1, respectively), such that the transistors 532 are turned on (e.g., operating in linear or saturation region, as described more below). Similarly, biasing generation circuit 510 may provide particular biasing voltages to the source select lines 519 and 517 (SGS0 and SGS1, respectively), such that the transistors 536 are turned on (e.g., operating in linear or saturation region, as described more below).

FIG. 5 further illustrates that each of the memory cells in string 534 has a word line connected to its control gate, similar to the memory cells 208 in string 206 described above. Also, because the dedicated memory block 530 is configured to generate a sensing current, not store data, the access lines 523 of memory cells in string 534 can be connected together to receive a control signal from biasing generation circuit 510. Biasing generation circuit 510 provides, via access lines 523, a particular biasing voltage or voltages to the memory cells in string 534 such that they are turned on (e.g., operating in linear or saturation region, as described in more detail below). As shown in FIG. 5, a source of one of select transistors 536 can be connected to a common source 216. Common source 216 is connected to all memory blocks in, for example, a memory plane. A drain of one of select transistors 532 can be connected to the data line 556 (e.g., a bit line). When select transistors 532, select transistors 536, and the string 534 of memory cells are all turned on, a sensing current flows through the column comprising select transistors 532 and 536, and memory cell string 534. The sensing current contributes to the overall current of the data line 556, and thus helps to improve the sensing operation speed.

The sensing current generated by dedicated memory block 530 may be configured to be any value. As such, the sensing current is configurable or trimmable. In one example, the sensing current can be configured by programming the threshold voltages (denoted as Vt) of the memory cells in string 534. In a memory device, each memory cell has a threshold voltage or a threshold voltage range associated with it. A memory cell is programmed to one of the voltage levels within a threshold voltage range. During a sensing operation (e.g., a read operation) of a memory cell, the controller (e.g., controller 115 or 135) determines which voltage level the memory cell currently has, based on its threshold voltage. Therefore, a memory cell can store multiple bits of data corresponding to multiple voltage levels. Depending on the number of voltage levels, the memory cell can be MLC, TLC, QLC, etc., as described above.

The memory cells in dedicated memory block 530 are not used for storing data, but for generating sensing current. However, the memory cells in block 530 can be programmed to have different threshold voltages such that different sensing current levels can be obtained. For example, with the same biasing voltage applied on access lines 523 (e.g., word lines connected to the control gates of string 534 of memory cells), the threshold voltage Vt of the memory cells in string 534 can be programmed to be a small voltage level to obtain a high sensing current (e.g., 15 nA); a medium voltage level to obtain a medium sensing current (e.g., 10 nA); and a large voltage level to obtain a small sensing current (e.g., 5 nA). In one example, the threshold voltage of the memory cells in string 534 is programmed to be a voltage range like 0-2 V or similarly low voltage ranges. The threshold voltage can even be a negative voltage (e.g., −0.1 V). This kind of low threshold voltage may also be referred to as the UV_Vt. A memory cell having a low threshold voltage can be turned on even if the biasing voltage applied on the access lines 523 is low. Therefore, having a low threshold voltage may ensure that that all memory cells in the dedicated memory block 530 can be turned on to generate sensing current during a sensing operation of a selected memory block. It is understood that the sensing currents generated by block 530 can be trimmed to have more or fewer current levels, not limited to three levels described above.

It is further understood that there are other ways to trim or configure the sensing current levels. For example, the select transistors 532 and 536 and memory cells in string 534 may be configured to have dimensions sufficiently large such that the dedicated memory block 530 can generate a larger sensing current (e.g., 15-55 nA) compared to the pillar current flowing through any of the memory blocks 552 (e.g., the pillar current of block 552A may be just 5 nA). In another example, the number of memory cells in string 534 of the dedicated memory block 530 may be less than that of a string in any of the memory block 552. As a result, the pillar resistance in string 534 may be smaller, and in turn the sensing current produced by dedicated memory block 530 can be greater. It is understood that the sensing current generated by dedicated memory block 530 can be configured by various ways and not limited to those described above.

As described above, dedicated memory block 530 receives biasing voltages and/or currents from biasing generation circuit 510. Biasing generation circuit 510 may include biasing circuits and/or one or more regulators. For illustrative purposes, FIG. 5 shows that biasing generation circuit 510 comprises biasing circuits like diode-connected transistors 512, 514, 516, and 518 (e.g., NMOS field-effect transistors) for biasing the select lines 513, 515, 517, and 519, respectively. The transistors 512, 514, 516, and 518 can be particularly sized to provide predetermined biasing voltages to turn on the select transistors 532 and 536 during a sensing operation of a selected memory block (e.g., block 552A). Biasing generation circuit 510 may also include a regulator 522 configured to generate a biasing voltage for driving the access lines 523. The regulator 522 may be, for example, a voltage regulator including one or more operational amplifiers (op-amps), current mirrors, current sources, and/or resistor dividers. The regulator 522, while shown as being included in biasing generation circuit 510, may be included in other part of the memory device 500. As described above, in a memory device, a memory controller (e.g., system controller 115 or local controller 135) may control a plurality of regulators to drive the access lines of the memory blocks. For example, one or more regulators may be used to drive the regular memory blocks 552. Dedicated memory block 530 can be configured substantially the same or similar to a memory block for storing data, like regulator memory blocks 552. Therefore, regulator 522 for driving the access lines 523 of dedicated memory block 530 can be the same as, or similar to, one of the plurality of regulators for driving the access lines of the regular memory blocks 552. In some examples, these regulators can be a part of a controller (e.g., bias generation control circuit 137 in controller 135) or separate circuitry (e.g., a part of circuit 109) as shown above in FIG. 1.

With continue reference to FIG. 5, during a sensing operation (e.g., read, program verification, etc.) of a memory cell of the selected block 552A, the sensing circuits (e.g., sense amplifiers) associated with data line 556 can sense the overall current of data line 556, and amplify any voltage difference that represent the data stored in the memory cell. During the operation, the clamp device 562 is turned on by a memory controller (e.g., controller 115 or 135), such that the current of data line 556 can be sensed by a sense circuit. The sense circuits may be a part of the page buffer, as described above. Without the sensing current generation capability, the data line current is just the pillar current flowing through the memory cell of the selected memory block 552A. With the sensing current generation capability disclosed herein, during a sensing operation, the controller can also be configured to control the dedicated memory block 530 to generate sensing current. Because the dedicated memory block 530 is connected to the same data line 556, the total current of data line 556 is the sum of the sensing current produced by dedicated memory block 530 and the pillar current flowing through the selected memory block 552A. As a result, the total data line current can be increased significantly and/or as desired. Correspondingly, when the data line current is increased, the data line settling time is reduced and the sense circuits can perform the sensing operations much faster (e.g., read the data stored in the selected memory cell much faster). This improves the overall memory operation efficiency and speed.

In some examples, the sensing current produced by dedicated memory block 530 can be configured such that the data line current is approximately constant. As shown in FIG. 5 and described above, the sensing current produced by block 530 can be trimmable to have different levels. Therefore, if the pillar currents flowing through different memory blocks 552A-552N are different, a controller can configure the biasing generation circuit 510 and/or the dedicated memory block 530 to generate different levels of sensing currents to compensate the differences of pillar currents between different memory blocks 552A-552N. For instance, if the pillar current flowing through a first selected memory block 552A is 5 nA, the dedicated memory block 530 can be configured (e.g., using any of the methods described above) to produce a sensing current of 55 nA. If the pillar current flowing through a second selected memory block 552B is 7 nA, the dedicated memory block 530 can be configured (e.g., using any of the methods described above) to produce a sensing current of 53 nA. And if the pillar current flowing through a third selected memory block 552C is 10 nA, the dedicated memory block 530 can be configured (e.g., using any of the methods described above) to produce a sensing current of 50 nA, and so forth. Thus, despite different memory blocks may have different pillar currents, the total data line current remains approximately a constant (e.g., 60 nA in the above three examples). In other examples, regardless of the pillar current differences between the memory blocks, the sensing current produced by the dedicated memory block 530 may remain unchanged (e.g., always 60 nA). As a result, the total data line current may vary if memory cells in different memory blocks are sensed.

With continued reference to FIG. 5, in some examples, the plurality of regular memory blocks 552 and the dedicated memory block 530 can both be a part of a memory plane. Referring back to FIG. 2D, each of the memory planes 261 may refer to a group of memory blocks 250. Thus, for example, the plurality of memory blocks 552 and the dedicated memory block 530 in FIG. 5 can be any of the memory blocks 250 within the same memory plane 261. In some instances, each memory plane has a dedicated memory block 530 for generating sensing current to improve the sensing speed of the memory cells in the memory blocks of the same memory plane. In some examples, a memory plane may have a sensing current generation set, which may include one or more memory blocks, one or more sub-blocks (strings of memory cells), one or more word lines of a memory block or sub-block.

With reference back to FIG. 5, as described above, biasing generation circuit 510 is controlled (e.g., by controller 115 or 135) to generate biasing voltages and/or currents for dedicated memory block 530. In some examples, biasing generation circuit 510 can be configured to bias the dedicated memory block 530 such that the select transistors 532/536 and the series-connected memory cells in the string 534 operate in the same or different operating regions. In one example, select transistors 532 and 536 are biased such that they operate in the saturation regions, while the series-connected memory cells in string 534 are biased such that they operate in the linear region. For a transistor (e.g., an NMOS), it operates in the linear region if the drain-source voltage (denoted by V_{ds}) is less than the difference of the gate-source voltage (denoted by V_{gs}) and the threshold voltage (denoted by Vₜ). That is, the transistor operates in the linear region if the V_{ds}<V_{gs}−Vₜ. The transistor operates in the saturation region if the V_{ds}>V_{gs}−Vₜ. The transistor is considered to be turned on if Ves is greater than or equal to Vₜ (i.e., V_{gs}≥Vₜ). The linear region and saturation region are both operating regions when the transistor is turned on. A transistor operates in the subthreshold region if the V_{gs} is less than Vₜ (i.e., V_{gs}<Vₜ). Thus, to operate a transistor in a certain region, its drain, source, and gate voltages can be set accordingly.

Referring to FIG. 5, using the select transistors 532 as an example, the select line 513 is connected to the control gate of select transistor 532 and thus the gate voltage is the voltage of select line 513 (SGD1). The drain voltage of this transistor 532 is the voltage of the data line 556. The source voltage of this transistor 532 is the drain voltage of the other transistor 532 having its gate connected to the select line 515 (SGD0). The gate, drain, and source voltages of transistors 532 can thus be determined by the voltages applied to the select lines 513 and 515, the voltage applied to the data line 556, and other voltages (e.g., the voltage applied to the access lines 523, and/or the voltages applied to the select lines 517 and 519). With the gate, drain, and source voltages, the operating regions of select transistors 532 can be determined based on the voltage differences between them, as described above. The operating regions of memory cells in string 534 can be similarly determined when the gate, drain, source voltages and threshold voltages are determined. And the operating regions of select transistors 536 can be similarly determined too.

When select transistors 532 and 536 are biased in the saturation region and the series-connected memory cells in string 534 are biased in the linear region, the sensing current generated by block 530 is controlled or adjusted by either the select transistors 532 or the select transistors 536, or both. Therefore, the level of the sensing current can be set by particularly configuring these selected transistors 532 and/or 536 (e.g., by setting the transistor sizes and biasing voltages applied to them).

In another example, when select transistors 532 and 536 are biased in the linear region and the series-connected memory cells in string 534 are biased in the saturation region, the sensing current generated by block 530 is controlled or adjusted by the memory cells in the string 534. For example, the level of the sensing current can be set by particularly configuring the threshold voltages (Vₜ) of the memory cells in string 534. In another example, both select transistors 532 and 536 and the series-connected memory cells in string 534 are biased in the saturation region. The level of sensing current can be controlled or adjusted by one or both select transistors 532 and 536 and the series-connected memory cells in string 534. Regardless of the way of setting the sensing current provided by the dedicated memory block 530, the sensing current can be set to contribute to the overall data line current, thereby improving the sensing operation speed. For example, the time delay caused by the data line 556 may be reduced by 2-10 times when the data line current is boosted from 5 nA (e.g., just the pillar current of the selected memory block 552) to 10 or 500 nA (e.g., the sum of the pillar current of the selected memory block 552 and the sensing current generated by the block 530).

With continued reference to FIG. 5, in some examples, memory device 500 includes a data line clamp device 562 configured to enable or disable sensing of the data line current. For example, data line clamp device 562 couples data line 556 to, or decouples data line 556 from, a sense amplifier of sense circuits. The sense circuits may be sense circuits 242 shown in FIG. 2C above, which can be located in a buffer portion 240. During a sensing operation, a controller (e.g., controller 115 or 135) can be configured to turn on data line clamp device 562 to sense the data line current. When a sensing operation is not performed for any of the blocks 552 coupled to data line 556, the controller turns off data line clamp device 562. In some examples, the clamp device 562, when turned on, operates in a subthreshold region (e.g., because the data line current is very small).

A sensing current for improving the sensing operation speed can be generated in various ways. For example, it can be generated from a dedicated memory block (e.g., block 530 shown in FIG. 5), or it can be generated using one or more un-used sub-blocks or un-used word lines in a Read Only Memory (ROM) block. One or more regulators in a memory device are configured to drive the dedicated memory block (e.g., either a dedicated block or an un-used sub-block of a ROM block) to generate the sensing current. As described above, the sensing current can then be combined with a pillar current of a selected memory block for improving the sensing operation speed. Example configurations of using a dedicated memory block and using un-used sub-blocks of a ROM block for generating the sensing current are described in detail below.

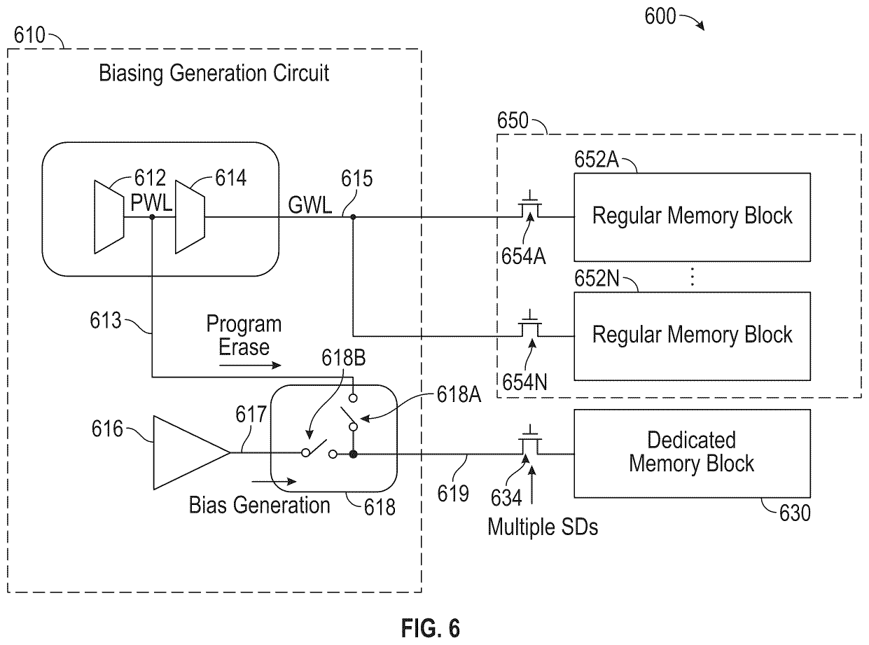

FIG. 6 illustrates an example memory device 600 using a dedicated memory block 630 to improve the data line current-sensing speed in accordance with examples as disclosed herein. The memory device 600 shown in FIG. 6 can be any of the memory devices described above (e.g., memory device 130 or 500). Memory device 600 comprises a biasing generation circuit 610, a dedicated memory block 630, and regular memory blocks 650. Regular memory blocks 650 include a plurality of regular memory blocks 652A-652N, and can be substantially the same or similar to the regular memory blocks 552 or 250 described above. Therefore, they are not repeatedly described.

In FIG. 6, the dedicated memory block 630 is a dedicated memory block for current generation. Similar to block 530 described above in connection with FIG. 5, block 630 may include a plurality of select transistors, a plurality of series-connected memory cells coupled to the select transistors; and a plurality of access lines (e.g., word lines). Each access line is coupled to a respective memory cell of the plurality of series-connected memory cells. The configuration of the select transistors, memory cells, and access lines of block 630 can be substantially the same as or similar to those of block 530 described above.

In some examples, the memory cells in dedicated memory block 630 are programmed to have their threshold voltages in a predetermined low voltage range of, e.g., 0-2V. This low threshold voltage range is also referred to as the UV_Vt. A memory cell having such a threshold voltage range is typically stable, in that its floating gate retaining charges has no or minimum charge loss or charge gain. Furthermore, as described above, there are many memory cells (e.g., hundreds) in a dedicated memory block 630. Therefore, RTS (random telegraph signal) noise can be averaged and reduced. RTS noise is characterized by discrete transitions in the signal current of a transistor device (e.g., a MOSFET). Similarly, other variations (e.g., process variation) can be averaged out.

As shown in FIG. 6, regular memory blocks 652A-652N are coupled to clamp devices 654A-654N, respectively. Each of clamp devices 654A-654N may represent multiple switches, also referred to as string drives (SDs). For example, claim device 654A may comprise multiple string drives, each of which is connected to a word line. When a memory cell associated with a particular word line is selected, the corresponding string drive connected to the particular word line is turned on, such that the selected memory cell can receive the biasing voltage from a regulator in biasing generation circuit 610. As shown in FIG. 6, dedicated memory block 630 may have a clamp device 634. However, because dedicated memory block 630 is for generating the sensing current to increase the data line current, not for storing data, it is not necessary to connect each word line in the dedicated memory block 630 to a different string drive. Therefore, the dedicated memory block 630 may have a reduced number of string drives (e.g., 30) in clamp device 634 compared to that for a regular memory block (e.g., hundreds). During a sensing operation, the string drives of claim device 634 can be controlled to turn on such that the dedicated memory block 630 receives biasing voltages provided by a regulator in biasing generation circuit 610.

With reference still to FIG. 6, biasing generation circuit 610 may include multiple regulators (e.g., regulators 612 and 616) for driving the regular memory blocks 650 and for driving the dedicated memory block 630. In one example, a first regulator 612 drives the regulator memory blocks. Regulator 612 can be controlled (e.g., by controller 115 or 135) to generate a signal 613. Signal 613 is also referred to as the principal word line (PWL) signal. In FIG. 6, a decoder 614 (e.g., a demultiplexer) is coupled to the regulator 612 to receive the PWL signal 613. Decoder 614 can also be controlled by a controller according to, for example, a row decoder used for selection of word line(s) of a memory block(s) for performing certain memory operations. The output signal 615 of decoder 614 is also referred to as the global word line (GWL) signal. The GWL signal 615 is used to drive all regular memory blocks 652A-5652N via string drives of clamp devices 654A-654N. Therefore, using the decoder 614 and string drives of claim devices 654A-654N, the PWL signal 613 can be applied to any word line of a selected memory cell in any of memory block 652A-652N.

Regulator 612 can be controlled to generate the PWL signal suitable for performing any types of memory operations. For example, based on the type of operation, regulator 612 can be controlled to generate the PWL signal (e.g., signal 613) to have different voltages. In an erase operation, for instance, the PWL signal may have a 0 V. In a program operation, the PWL signal may have 20V. In a sensing operation (e.g., a read operation or a program verification operation), the PWL signal may have a voltage range (e.g., −2.5V-2V), because the threshold voltages of the memory cell may vary. The PWL signal 613 (or the GWL signal 615 through the decoder 614) is applied to the word lines connected to memory cells in regular memory blocks 652A-652N. It is understood that to perform memory operations, corresponding biasing voltages may need to be applied to the bit lines. For instance, for the erase operation and program operation, the bit line voltages may be 20V and 0V respectively.

With continued reference to FIG. 6, in one embodiment, a second regulator 616 may be used to drive the dedicated memory block 630 to generate the sensing current to increase the total data line current during a sensing operation. In the example shown in FIG. 6, one or more switches 618A and 618B form a switch network 618. The switch network 618 is controlled (e.g., by a controller 115 or 135) to couple regulators 612 and 616 to, or decouple them from, dedicated memory block 630. During a sensing operation, the data line current of a selected memory cell in a regular memory block 652 is sensed. As described above, the dedicated memory block 630 is configured to generate the sensing current to increase the total data line current. Regulator 616 is controlled (e.g., by controller 115 or 135) to provide a particular biasing voltage to the word lines of memory cells in the dedicated memory block 630. The biasing voltage for sensing current generation, in one example, can have a low voltage range with about 0-2V (e.g., approximately in the UV_Vt range). The biasing voltage can also vary depending on if the memory cells in the dedicated memory block 630 operate in the linear region or the saturation region, as described above.

Furthermore, as illustrated in FIG. 6, to provide the particular biasing voltage from regulator 616 to dedicated memory block 630, switch network 618 can be configured (e.g., by a controller 115 or 135) such that switch 618B is closed and switch 618A is open. In this manner, the second regulator 616 is coupled to the dedicated memory block 630 and the first regulator 612 is decoupled from the dedicated memory block 630. Thus, during a sensing operation (e.g., read operation or program verification operation), first regulator 612 is used to provide a first bias voltage to the word line of a selected memory cell in a regular memory block 652; while the second regulator 616 is used to provide a second bias voltage to the word lines of the memory cells in the dedicated memory block 630. The first bias voltage may be different from the second bias voltage. For instance, the first bias voltage may be in the range of −2.5V-2V, while the second bias voltage may be in the range of 0-2V.

During a non-sensing operation (e.g., an erase operation, a program operation), the first regulator 612 can be used to apply a particular biasing voltage to a word line of a memory cell in the regular memory block 652 and to word lines of memory cells in the dedicated memory block 630. In this situation, the switch network 618 can be configured such that switch 618A is closed and switch 618B is open. As a result, the first regulator 612 is coupled to the dedicated memory block 630 and the regular memory blocks 652. The second regulator 616 is decoupled from the dedicated memory block 630.

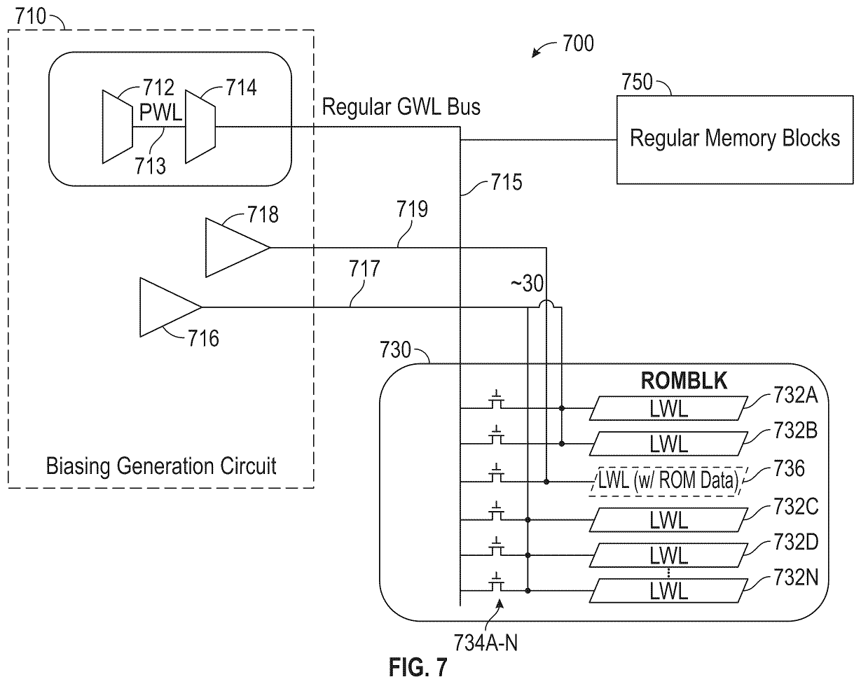

The above examples use a dedicated memory block to generate the sensing current for increasing the total data line current such that the sensing operation speed is improved. FIG. 7 illustrates an example memory device 700 using a Read Only Memory (ROM) block 730 to improve the data line current-sensing speed in accordance with examples as disclosed herein. Device 700 includes a biasing generation circuit 710 comprising one or more regulators, a ROM block 730, and regular memory blocks 750. Regular memory blocks 750 can be substantially the same as or similar to regular memory blocks 550 or 650 described above, and thus are not repeatedly described. Some of the clamp devices and string drives are not shown in FIG. 7 for simplicity.

With reference to FIG. 7, a ROM block 730 includes local word lines (LWL) 732A-732N and 736. These local word lines are connected with memory cells in sub-blocks (not shown) of ROM block 730. For instance, LWL 736 is connected to a sub-block for storing read-only data in ROM block 730. The read-only data may include information specific to memory device 700. For example, the read-only data may include memory device trim information, redundancy information, and REM (replacement of memory) information. These read-only data are read out by a controller (e.g., a host system controller or a memory controller) during the initiation of the memory device. The read-only data may indicate, for example, which memory blocks in memory device 700 are bad blocks and/or microcontroller instructions for fixing errors or replacing information in bad blocks. Typically, a ROM block is implemented using SLC type memory cells.

In some embodiments, one or more sub-blocks and/or word lines in ROM block 730 are un-used. That is, they are not used to store read-only data. These un-used sub-blocks and/or associated word lines of memory cells in ROM block 730 can therefore be used to generate sensing current for increasing the total data line current during a sensing operation of a selected memory cell. In FIG. 7, local word lines 732A-732N are connected to un-used sub-blocks (not shown but could be similar to those described above); while local word line 736 is connected to used sub-blocks storing read-only data. In one example, because local word lines 732A-732N are un-used word lines connected to un-used sub-blocks, one or more of word lines 732A-732N and their associated sub-blocks can be configured to be a part of the dedicated memory block for generating sensing current. And since the memory cells of the sub-blocks connected to LWL 732A-732N do not store any data, LWL 732A-732N can be physically connected together to receive the same biasing voltage.

FIG. 7 further illustrates that device 700, similar to device 600, comprises multiple regulators 712, 716, and 718 in a biasing generation circuit 710. Regulator 712 is used to drive the regular memory blocks 750 (via a decoder 714 similar to decoder 614). Regulator 712 can be similar to regulator 612 described above, and can include op amps, current mirrors, current sources, resistor dividers, etc., configured to generate desired biasing voltages and/or currents. For example, regulator 712 generates a PWL signal 713. After demultiplexing by decoder 714, PWL signal 713 becomes a GWL signal 715. Regulator 712 is further connected to clamp devices 734A-734N, which have multiple string drives for coupling the GWL signal 715 to, or decoupling the GWL signal 715 from, the local word lines 732 and 736. Similar to regulator 612, regulator 712 can be controlled to generate various biasing voltages for performing different operations to the memory cells in ROM block 730 (e.g., erase, read, etc.).

As described above, the un-used sub-blocks and un-used word lines in ROM block 730 can be configured as a part of the dedicated memory block for generating a sensing current. The un-used sub-blocks are connected to LWLs 732A-732N, which are physically coupled together. A third regulator 716 is used to drive these LWLs 732A-732N such that a particular biasing voltage is applied to these LWLs 732 of the memory cells of the un-used sub-blocks. Regulator 716 can be controlled to apply the particular biasing voltages for generating the sensing current during a sensing operation, similar to those described above for regulator 522 and 616.

FIG. 7 further illustrates that, in some examples, a fourth regulator 718 is controlled to drive the LWL 736 connected to a used sub-block in ROM block 730. Regulator 718 can be configured to generate a signal 719 having a biasing voltage for reading data stored in the used sub-block of ROM block 730. Thus, in this example, the regulator 712 is controlled to generate GWL signal 715 for performing certain operations like read or erase of all sub-blocks in ROM block 730 (regardless of used or un-used); regulator 716 is controlled to apply a signal 717 for generating the sensing current using the un-used sub-blocks in ROM block 730; and regulator 718 is controlled to apply a signal 719 for performing other operations (e.g., an read operation for reading the stored data in used sub-block of ROM block 730). All regulators in biasing generation circuit 710 can be controlled by a controller (e.g., controller 115 or 135).

In some examples, memory device 700 may also include a switch network (not shown) for coupling and decoupling the regulators 712, 716, and 718 to the ROM block 730. Such a switch network can be implemented using one or more switches similar to those of network 618 shown in FIG. 6, and for simplicity it is not shown in FIG. 7. In other examples, a switch network may not be necessary for memory device 700.

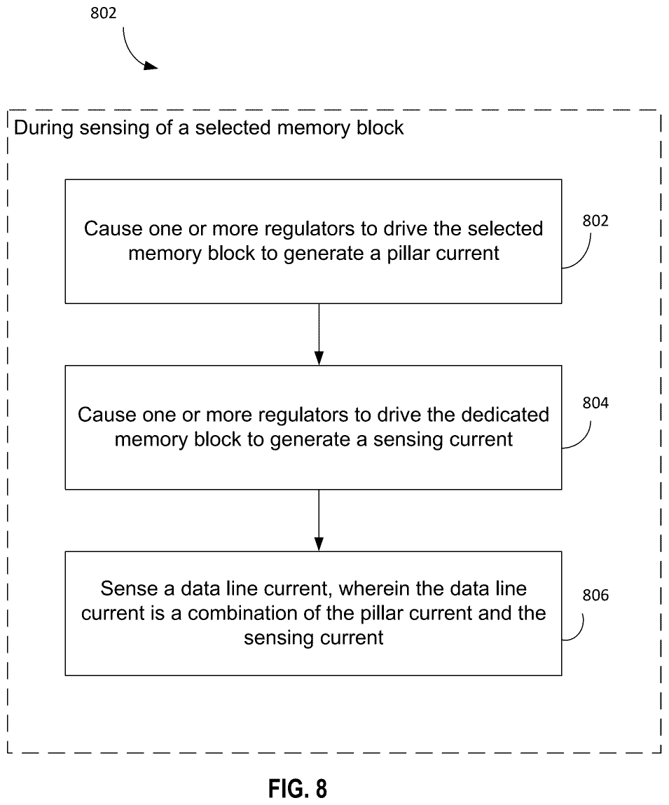

FIG. 8 illustrates a flowchart showing a method 800 that supports techniques for fast data line current sensing in accordance with examples as disclosed herein. At least some of the blocks in method 800 can be performed by a memory controller (e.g., controller 115 or 135) during sensing of a selected memory block of a plurality of memory blocks in a memory device. In block 802, the memory controller causes one or more regulators (e.g., regulators 612 or 712) to drive the selected memory block to generate a pillar current flowing through a pillar of the selected memory block. The pillar is shared by multiple stacked memory cells of the selected memory block, as shown in the example in FIG. 4A. In block 804, the memory controller causes the one or more regulators to drive the dedicated memory block (e.g., block 530, 630, 730) to generate a sensing current. In block 806, sense circuits sense a data line current, which is a combination of the pillar current and the sensing current. Method 800 may include additional blocks not shown in FIG. 8. For example, method 800 may include another block, in which the memory controller causes the one or more regulators to program a plurality of series-connected memory cells in the dedicated memory block to have a predetermined threshold voltage, such that all memory cells in the dedicated memory block are turned on for generating the sensing current during sensing of the selected memory block. As another example, method 800 may include another block, in which a biasing generation circuit is configured to bias the plurality of selected transistors and the plurality of series-connected memory cells in the same or different operating regions. As another example, method 800 may include another block, in which the memory controller enables or disables a data line clamp device (e.g., device 562) to enable or disable sensing of the data line current.

It should be noted that the described techniques include possible implementations, and that the operations and the blocks may be rearranged, reordered, or otherwise modified and that other implementations are possible. Further, portions from two or more of the methods may be combined.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed and second condition or action may at least partially occur as a result of the previous condition or action occurring (whether directly after or after one or more other intermediate conditions or actions occurring after the first condition or action).

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., the majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processor, firmware, or any combination thereof. If implemented in software executed by a processor (e.g., processor 310 of FIG. 3), the functions may be stored on or transmitted over, as one or more instructions or code, a computer-readable medium. Other examples and implementations are within the scope of the disclosure and appended claims. For example, due to the nature of software, the described functions can be implemented using software executed by a processor, hardware, firmware, hardwiring, or combinations of any of these. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory device, comprising:
a data line;
a plurality of memory blocks coupled to the data line;
a dedicated memory block coupled to the data line, the dedicated memory block being controllable to generate a sensing current; and
a memory controller configured to, during sensing of a selected memory block of the plurality of memory blocks, cause one or more regulators to:
drive the selected memory block such that a pillar current flows through a pillar of the selected memory block, the pillar being shared by multiple stacked memory cells of the selected memory block, and
drive the dedicated memory block to generate the sensing current;
a sense amplifier configured to sense a data line current, wherein the data line current is a combination of the pillar current and the sensing current.

2. The memory device of claim 1, wherein the plurality of memory blocks and the dedicated memory block are both a part of a memory plane.

3. The memory device of claim 1, further comprising a biasing generation circuit coupled to the dedicated memory block, the biasing generation circuit comprising at least one of the one or more regulators configured to drive the dedicated memory block to obtain the sensing current, the sensing current being trimmable.

4. The memory device of claim 3, wherein the dedicated memory block is biased such that the data line current is approximately constant during sensing of any one of the plurality of memory blocks.

5. The memory device of claim 3, wherein the dedicated memory block comprises:
a plurality of select transistors;
a plurality of series-connected memory cells coupled to the select transistors; and
a plurality of word lines, each being coupled to a respective memory cell of the plurality of series-connected memory cells.

6. The memory device of claim 5, wherein the plurality of word lines are physically coupled together, and wherein at least one of the one or more regulators is coupled to the plurality of word lines, the at least one of the one or more regulators being configured to apply a word line biasing voltage to the plurality of word lines.

7. The memory device of claim 5, wherein the memory controller is further configured to cause the one or more regulators to program the plurality of series-connected memory cells in the dedicated memory block to have a predetermined threshold voltage, such that all memory cells in the dedicated memory block are turned on for generating the sensing current during sensing of the selected memory block.

8. The memory device of claim 5, wherein the biasing generation circuit is further configured to bias the plurality of selected transistors and the plurality of series-connected memory cells in different operating regions.

9. The memory device of claim 5, wherein the biasing generation circuit is further configured to bias the plurality of selected transistors and the plurality of series-connected memory cells in a same operating region.

10. The memory device of claim 1, further comprising:
a data line clamp device configured to enable or disable sensing of the data line current, wherein the sense amplifier is coupled to the data line clamp device, the sense amplifier being configured to sense the data line current.

11. A memory device comprising:
a plurality of memory blocks of a memory plane;
a dedicated memory block in the memory plane, the dedicated memory block being controllable to generate a sensing current;
one or more regulators configured to, during sensing of a selected memory block of the plurality of memory blocks:
drive the selected memory block to generate a pillar current, and
drive the dedicated memory block to generate the sensing current; and
a sense amplifier configured to sense a combination of the pillar current and the sensing current.

12. The memory device of claim 11, wherein the dedicated memory block is a dedicated memory block for sensing current generation, the dedicated memory block comprising:
a plurality of select transistors;
a plurality of series-connected memory cells coupled to the select transistors; and
a plurality of access lines, each access line of the plurality of access lines being coupled to a respective memory cell of the plurality of series-connected memory cells.

13. The memory device of claim 11, further comprising one or more switches, wherein the one or more regulators comprise a first regulator and a second regulator.

14. The memory device of claim 13, wherein the one or more switches are controllable to, during the sensing of the selected memory block:
couple the second regulator to the dedicated memory block such that the second regulator drives the dedicated memory block to generate the sensing current; and
decouple the first regulator from the dedicated memory block.

15. The memory device of claim 13, wherein the one or more switches are controllable to, during other non-sensing operations of the selected memory block or the dedicated memory block:
couple the first regulator to the dedicated memory block; and
decouple the second regulator from the dedicated memory block.

16. The memory device of claim 11, wherein the dedicated memory block comprises at least one of one or more un-used sub-blocks or one or more un-used word lines in a Read Only Memory (ROM) block.

17. The memory device of claim 16, wherein the un-used word lines are associated with the un-used sub-blocks, and the un-used word lines in the ROM block are physically connected.

18. The memory device of claim 16, wherein the one or more regulators comprise:
a third regulator coupled to the un-used sub-blocks or the un-used word lines such that the un-used sub-blocks generate the sensing current during sensing of the selected memory block; and
a fourth regulator coupled to one or more used sub-blocks or one or more used word lines in the ROM block, the fourth regulator being different from the third regulator.

19. A system comprising:
a processor; and
a memory device coupled to the processor, the memory device comprising:
a data line;
a plurality of memory blocks coupled to the data line;
a dedicated memory block coupled to the data line, the dedicated memory block being controllable to generate a sensing current; and
a memory controller configured to, during sensing of a selected memory block of the plurality of memory blocks, cause one or more regulators to:
drive the selected memory block such that a pillar current flows through a pillar of the selected memory block, the pillar being shared by multiple stacked memory cells of the selected memory block, and
drive the dedicated memory block to generate the sensing current;
a sense amplifier configured to sense a data line current,
wherein the data line current is a combination of the pillar current and the sensing current.

20. A method performed by a memory device comprising a plurality of memory blocks and a dedicated memory block, the method comprising:
during sensing of a selected memory block of the plurality of memory blocks, causing one or more regulators to:
drive the selected memory block to generate a pillar current flowing through a pillar of the selected memory block, the pillar being shared by multiple stacked memory cells of the selected memory block, and
drive the dedicated memory block to generate the sensing current; and
sensing, by sense circuits, a data line current, wherein the data line current is a combination of the pillar current and the sensing current.
